(19) United States
(12) Patent Application Publication
(10) Pub. No.: US 2025/0008787 A1
(43) Pub. Date: Jan. 2, 2025

(54) DISPLAY SUBSTRATE AND DISPLAY APPARATUS

(71) Applicant: BOE Technology Group Co., Ltd., Beijing (CN)

(72) Inventors: Hao Zhang, Beijing (CN); Pinfan Wang, Beijing (CN); Bingwei Wang, Beijing (CN)

(73) Assignee: BOE Technology Group Co., Ltd., Beijing (CN)

(21) Appl. No.: 18/264,063

(22) PCT Filed: Nov. 17, 2022
(86) PCT No.: PCT/CN2022/132531

§ 371 Date: Aug. 2, 2023

(51) Int. Cl. H10K 59/131; H10K 59/121; H10K 59/80

(52) U.S. Cl. CPC H10K 59/131; H10K 59/1213; H10K 59/1216; H10K 59/873

(57) ABSTRACT

A display substrate is provided. The display substrate includes a plurality of islands and a plurality of bridges connecting the plurality of islands. The display substrate comprises a signal line, wherein the signal line comprises: a first bridge connecting line at least partially in a first bridge of the plurality of bridges; a second bridge connecting line at least partially in a second bridge of the plurality of bridges; and a connecting structure at least partially in a respective island of the plurality of islands, connecting the first bridge connecting line with the second bridge connecting line; wherein at least a portion of the connecting structure is in a layer different from the first bridge connecting line or the second bridge connecting line.

### TECHNICAL FIELD

The present invention relates to display technology, more particularly, to a display substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a plurality of islands and a plurality of bridges connecting the plurality of islands; wherein the display substrate comprises a signal line; wherein the signal line comprises: a first bridge connecting line at least partially in a first bridge of the plurality of bridges; a second bridge connecting line at least partially in a second bridge of the plurality of bridges; and a connecting structure at least partially in a respective island of the plurality of islands, connecting the first bridge connecting line with the second bridge connecting line; wherein at least a portion of the connecting structure is in a layer different from the first bridge connecting line or the second bridge connecting line.

Optionally, the first bridge connecting line connects the connecting structure with a connecting structure in an adjacent island of the plurality of islands in a first adjacent column and in a same row; and the second bridge connecting line connects the connecting structure with a connecting structure in an adjacent island of the plurality of islands in a second adjacent column and in a same row.

Optionally, the first bridge connecting line connects the connecting structure with a connecting structure in an adjacent island of the plurality of islands in a first adjacent row and in a same column; and the second bridge connecting line connects the connecting structure with a connecting structure in an adjacent island of the plurality of islands in a second adjacent row and in a same column.

Optionally, at least the portion of the connecting structure is in a first conductive layer; and the first bridge connecting line and the second bridge connecting line are in a first signal line layer spaced apart from the first conductive layer by one or more insulating layers.

Optionally, the display substrate comprises a plurality of gate lines; wherein the signal line is a respective gate line of the plurality of gate lines; the first bridge connecting line is a first bridge gate connecting line; and the second bridge connecting line is a second bridge gate connecting line; wherein the connecting structure comprises a first gate branch line connecting the first bridge gate connecting line and the second bridge gate connecting line; the first gate branch line is configured to provide a gate scanning signal to a data write transistor and a compensating transistor in a pixel driving circuit in the respective island.

Optionally, the connecting structure further comprises: a second gate branch line configured to provide a control signal to a reset transistor; and one or more gate connecting lines connecting the first gate branch line with the second gate branch line; wherein the first gate branch line and the second gate branch line are in the first conductive layer; and the one or more gate connecting lines are in the first signal line layer.

Optionally, the display substrate comprises a plurality of light emitting control signal lines; wherein the signal line is a respective light emitting control signal line of the plurality of light emitting control signal lines; the first bridge connecting line is a first bridge light emitting signal connecting line; and the second bridge connecting line is a second bridge light emitting signal connecting line; wherein the connecting structure comprises a light emitting signal connecting line connecting the first bridge light emitting signal connecting line with the second bridge light emitting signal connecting line; and the light emitting signal connecting line is configured to provide a light emitting control signal to a first light emitting control transistor and a second light emitting control transistor.

Optionally, the display substrate comprises a plurality of reset control signal lines; wherein the signal line is a respective reset control signal line of the plurality of reset control signal lines; the first bridge connecting line is a first bridge reset control signal connecting line; and the second bridge connecting line is a second bridge reset control signal connecting line; wherein the connecting structure comprises a reset control signal connecting line connecting the first bridge reset control signal connecting line and the second bridge reset control signal connecting line.

Optionally, the display substrate comprises a plurality of data lines; wherein the signal line is a respective data line of the plurality of data lines; the first bridge connecting line is a first bridge data line; the second bridge connecting line is a second bridge data line; wherein the connecting structure comprises: a first data branch line connected to the first bridge data line; a second data branch line connected to the second bridge data line; and a data connecting line connecting the first data branch line and the second data branch line.

Optionally, the first bridge data line, the second bridge data line, and the data connecting line are in the first signal line layer; and the first data branch line and the second data branch line are in the first conductive layer.

Optionally, at least the portion of the connecting structure is in a second conductive layer; and the first bridge connecting line and the second bridge connecting line are in a second signal line layer spaced apart from a first conductive layer by one or more insulating layers.

Optionally, the display substrate comprises a plurality of reset signal lines; wherein the signal line is a respective reset signal line of the plurality of reset signal lines; the first bridge connecting line is a first bridge reset signal line; and the second bridge connecting line is a second bridge reset signal line; wherein the connecting structure comprises: a first reset signal branch line connected to the first bridge reset signal line; a second reset signal branch line connected to the second bridge reset signal line; and one or more first reset signal connecting lines connecting the first reset signal branch line with the second reset signal branch line.

Optionally, the first reset signal branch line and the second reset signal branch line are in the second conductive layer; and the one or more first reset signal connecting lines are in a first signal line layer.

In another aspect, the present disclosure provides a display substrate, comprising a plurality of islands and a plurality of bridges connecting the plurality of islands; wherein the display substrate comprises a first voltage supply network; wherein the first voltage supply network comprises a plurality of first connecting structures in a display area of the display substrate, a first row connecting line, a second row connecting line, a first column connecting line, and a second column connecting line; a respective first connecting structure of the plurality of first connecting structures is connected by the first row connecting line, the second row connecting line, the first column connecting line, and the second column connecting line, to four adjacent first connecting structures, respectively; and the first row connecting line, the second row connecting line, the first column connecting line, and the second column connecting line are in four different bridges of the plurality of bridges.

Optionally, the first row connecting line connects the respective first connecting structure with a first connecting structure in a first adjacent row and in a same column together; the second row connecting line connects the respective first connecting structure with a first connecting structure in a second adjacent row and in a same column together; and the first adjacent row and the second adjacent row are two different rows on two different sides, along a column direction, of a present row having the respective first connecting structure.

Optionally, the first column connecting line connects the respective first connecting structure with a first connecting structure in a first adjacent column and in a same row together; the second column connecting line connects the respective first connecting structure with a first connecting structure in a second adjacent column and in a same row together; and the first adjacent column and the second adjacent column are two different columns on two different sides, along a row direction, of a present column having the respective first connecting structure.

Optionally, the respective first connecting structure comprises a first connecting line and a second connecting line electrically connected to each other; the first connecting line is connected to the first row connecting line and the first column connecting line; and the second connecting line is connected to the second row connecting line and the second column connecting line.

Optionally, the respective first connecting structure further includes a cathode connecting line and a cathode connecting pad connecting the first connecting line and the second connecting line together; and at least one of the cathode connecting line and the cathode connecting pad is further connected to a cathode.

Optionally, the display substrate further comprises a second voltage supply network; wherein the second voltage supply network comprises a plurality of second connecting structures in a display area of the display substrate, a third row connecting line, a fourth row connecting line, a third column connecting line, and a fourth column connecting line; a respective second connecting structure of the plurality of second connecting structures is connected by the third row connecting line, the fourth row connecting line, the third column connecting line, and the fourth column connecting line, to four adjacent second connecting structures, respectively; the third row connecting line, the fourth row connecting line, the third column connecting line, and the fourth column connecting line are in the four different bridges.

Optionally, the third row connecting line connects the respective second connecting structure with a second connecting structure in a first adjacent row and in a same column together; the fourth row connecting line connects the respective second connecting structure with a second connecting structure in a second adjacent row and in a same column together; the first adjacent row and the second adjacent row are two different rows on two different sides, along a column direction, of a present row having the respective second connecting structure.

Optionally, the third column connecting line connects the respective second connecting structure with a second connecting structure in a first adjacent column and in a same row together; the fourth column connecting line connects the respective second connecting structure with a second connecting structure in a second adjacent column and in the same row together; and the first adjacent column and the second adjacent column are two different columns on two different sides, along a row direction, of a present column having the respective second connecting structure.

Optionally, the respective second connecting structure comprises: a third connecting line and a fourth connecting line electrically connected to each other; and one or more voltage supply connecting lines connecting the third connecting line and the fourth connecting line together, the one or more voltage supply connecting lines being in a layer different from the third connecting line and the fourth connecting line; wherein the third connecting line is connected to the third row connecting line and the third column connecting line; the fourth connecting line is connected to the fourth row connecting line and the fourth column connecting line; and the third connecting line and the fourth connecting line are in a first conductive layer; the one or more voltage supply connecting lines are in a first signal line layer; and the third row connecting line, the third column connecting line, the fourth row connecting line, and the fourth column connecting line are in a second signal line layer.

Optionally, the first row connecting line and the third row connecting line are in a same first bridge; the second row connecting line and the fourth row connecting line are in a same second bridge; the first column connecting line and the third column connecting line are in a same third bridge; and the second column connecting line and the fourth column connecting line are in a same fourth bridge.

In another aspect, the present disclosure provides a display substrate, comprising a plurality of islands and a plurality of bridges connecting the plurality of islands; wherein the display substrate comprises: a base substrate; a planarization layer; an encapsulating layer on a side of the planarization layer away from the base substrate; and one or more first grooves in a respective island of the plurality of islands, the one or more first grooves at least partially extending into the planarization layer; and a respective first groove of the one or more first grooves substantially surrounds a region having transistors and capacitors of one or more pixel driving circuits of the respective island; wherein the encapsulating layer comprises one or more first pillars; a respective first pillar of the one or more first pillars extends into the respective first groove; and the respective first pillar substantially surrounds a region having transistors and capacitors of the one or more pixel driving circuits of the respective island.

Optionally, the display substrate further comprises one or more second grooves extending through the planarization layer; wherein the encapsulating layer further comprises one or more second pillars; and a respective second pillar of the one or more second pillars extends into a respective second groove of the one or more second grooves.

Optionally, the display substrate further comprises an inter-layer dielectric layer on a side of the planarization layer away from the encapsulating layer; a first passivation layer on a side of the planarization layer closer to the encapsulating layer; and a second passivation layer on a side of the first passivation layer and the planarization layer closer to the encapsulating layer; wherein the respective second pillar is in direct contact with the second passivation layer.

Optionally, the display substrate further comprises one or more signal lines, which cross over the one or more first pillars and the one or more second pillars; wherein the one or more signal line comprises a portion in a signal line layer and a portion in a conductive layer; an orthographic projection of the portion in the conductive layer of the one or more signal lines on the base substrate partially overlaps with an orthographic projection of the one or more first pillars and the one or more second pillars on the base substrate.

In another aspect, the present disclosure provides a display apparatus, comprising the display substrate described herein or fabricated by a method described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating a display area and a peripheral area in a display substrate in some embodiments according to the present disclosure.

FIG. 2 is a schematic diagram illustrating the structure of a display substrate in some embodiments according to the present disclosure.

FIG. 3 is a schematic diagram illustrating the structure of a display substrate in some embodiments according to the present disclosure.

FIG. 4 is a schematic diagram illustrating a portion of a display area in a display substrate in some embodiments according to the present disclosure.

FIG. 5A is a circuit diagram illustrating the structure of a pixel driving circuit in some embodiments according to the present disclosure.

FIG. 5B is a circuit diagram illustrating the structure of a pixel driving circuit in some embodiments according to the present disclosure.

FIG. 5C is a circuit diagram illustrating the structure of a pixel driving circuit in some embodiments according to the present disclosure.

FIG. 6A is a timing diagram illustrating the operation of a pixel driving circuit in some embodiments according to the present disclosure.

FIG. 6B is a timing diagram illustrating the operation of a pixel driving circuit in some embodiments according to the present disclosure.

FIG. 7A is a diagram illustrating the structure of the structure of a display substrate in some embodiments according to the present disclosure.

FIG. 7B is a diagram illustrating the structure of a semiconductor material layer in the display substrate depicted in FIG. 7A.

FIG. 7C is a diagram illustrating the structure of a first conductive layer in the display substrate depicted in FIG. 7A.

FIG. 7D is a diagram illustrating the structure of a second conductive layer in the display substrate depicted in FIG. 7A.

FIG. 7E is a diagram illustrating the structure of a first signal line layer in the display substrate depicted in FIG. 7A.

FIG. 7F is a diagram illustrating the structure of a second signal line layer in the display substrate depicted in FIG. 7A.

FIG. 8 is a cross-sectional view along an A-A′ line in FIG. 7A.

FIG. 9A is a schematic diagram illustrating the structure of a portion of a display area in a display substrate in some embodiments according to the present disclosure.

FIG. 9B is a diagram illustrating the structure of a semiconductor material layer in the display substrate depicted in FIG. 9A.

FIG. 9C is a diagram illustrating the structure of a first conductive layer in the display substrate depicted in FIG. 9A.

FIG. 9D is a diagram illustrating the structure of a second conductive layer in the display substrate depicted in FIG. 9A.

FIG. 9E is a diagram illustrating the structure of an inter-layer dielectric layer in the display substrate depicted in FIG. 9A.

FIG. 9F is a diagram illustrating the structure of a first signal line layer in the display substrate depicted in FIG. 9A.

FIG. 9G is a diagram illustrating the structure of a first planarization layer in the display substrate depicted in FIG. 9A.

FIG. 9H is a diagram illustrating the structure of a second signal line layer in the display substrate depicted in FIG. 9A.

FIG. 9I is a diagram illustrating the structure of a second planarization layer in the display substrate depicted in FIG. 9A.

FIG. 9J is a diagram illustrating the structure of an anode material layer in the display substrate depicted in FIG. 9A.

FIG. 9K is a diagram illustrating the structure of a pixel definition layer in the display substrate depicted in FIG. 9A.

FIG. 9L is a diagram illustrating the structure of a light emitting layer in the display substrate depicted in FIG. 9A.

FIG. 9M is a diagram illustrating the structure of a cathode material layer in the display substrate depicted in FIG. 9A.

FIG. 9N is a cross-sectional view along a B-B′ line in FIG. 9A.

FIG. 10 illustrates the structure of a respective gate line of a plurality of gate lines configured to provide gate scanning signals to a row of islands of a plurality of islands in a display substrate in some embodiments according to the present disclosure.

FIG. 11 illustrates the structure of a respective light emitting control signal line of a plurality of light emitting control signal lines configured to provide light emitting control signals to a row of islands of a plurality of islands in a display substrate in some embodiments according to the present disclosure.

FIG. 12 illustrates the structure of a respective reset signal line of a plurality of reset signal lines configured to provide reset signals to a row of islands of a plurality of islands in a display substrate in some embodiments according to the present disclosure.

FIG. 13 illustrates the structure of a respective reset control signal line of a plurality of reset control signal lines configured to provide reset control signals to a row of islands of a plurality of islands in a display substrate in some embodiments according to the present disclosure.

FIG. 14 illustrates the structure of a respective data line of a plurality of data lines configured to provide data signals to a column of islands of a plurality of islands in a display substrate in some embodiments according to the present disclosure.

FIG. 15 illustrates a first voltage supply network in a display area in a display substrate in some embodiments according to the present disclosure.

FIG. 16 illustrates a second voltage supply network in a display area in a display substrate in some embodiments according to the present disclosure.

FIG. 17 is a cross-sectional view along a C-C′ line in FIG. 9A.

FIG. 18 illustrates layout of signal lines in a region of the display substrate.

FIG. 19 is a cross-sectional view along a D-D′ line in FIG. 9A.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a display substrate and a display apparatus that substantially obviate one or more of the problems due to limitations and disadvantages of the related art. In one aspect, the display substrate includes a plurality of islands and a plurality of bridges connecting the plurality of islands. Optionally, the display substrate includes a signal line. Optionally, the signal line includes a first bridge connecting line at least partially in a first bridge of a plurality of bridges; a second bridge connecting line at least partially in a second bridge of the plurality of bridges; and a connecting structure at least partially in a respective island of the plurality of islands, connecting the first bridge connecting line with the second bridge connecting line. Optionally, at least a portion of the connecting structure is in a layer different from the first bridge connecting line or the second bridge connecting line.

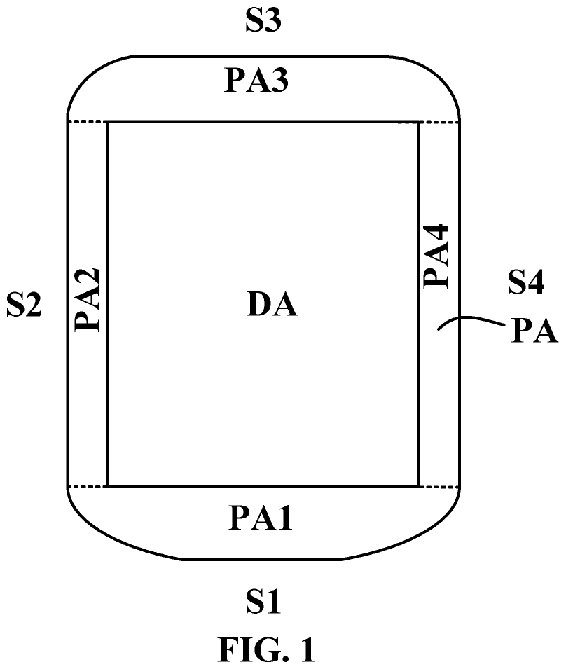

FIG. 1 is a schematic diagram illustrating a display area and a peripheral area in a display substrate in some embodiments according to the present disclosure. Referring to FIG. 1, in some embodiments, the display substrate includes a display area DA and a peripheral area PA. In some embodiments, the peripheral area PA includes a first sub-area PA1 on a first side S1 of the display area DA, a second sub-area PA2 on a second side S2 of the display area DA, a third sub-area PA3 on a third side S3 of the display area DA, a fourth sub-area PA4 on a fourth side S4 of the display area DA. Optionally, the first side S1 and the third side S3 are opposite to each other. Optionally, the second side S2 and the fourth side S4 are opposite to each other. Optionally, the first sub-area PA1 is a sub-area where signal lines of the display substrate are connected to an integrated circuit.

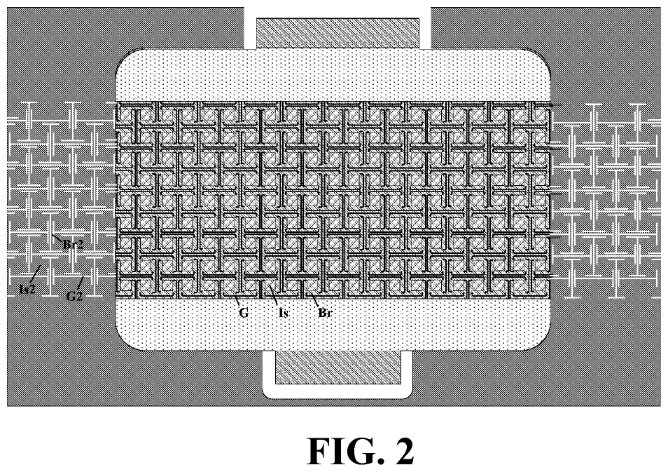

FIG. 2 is a schematic diagram illustrating the structure of a display substrate in some embodiments according to the present disclosure. Referring to FIG. 2, the display substrate in some embodiments is a stretchable display substrate. As used herein, the term “stretchable” refers to the ability of a material, structure, device or device component to be strained in tension (e.g., being made longer and/or wider) without undergoing permanent deformation or failure such as fracture, e.g., the ability to elongate at least 10% of its length without permanently deforming, tearing, or breaking. The term is also meant to encompass substrates having components (whether or not the components themselves are individually stretchable as stated above) that are configured in such a way so as to accommodate a stretchable, inflatable, or expandable surface and remain functional when applied to a stretchable, inflatable, or otherwise expandable surface that is stretched, inflated, or otherwise expanded respectively. The term is also meant to encompass substrates that may be elastically and/or plastically deformable (i.e. after being stretched, the substrate may return to its original size when the stretching force is released or the substrate may not return to its original size and in some examples, may remain in the stretched form) and the deformation (i.e. stretching and optionally flexing) may occur during manufacture of the substrate (e.g. with the substrate being stretched and optionally flexed to form its final shape), during assembly of a device incorporating the substrate (which may be considered part of the manufacturing operation) and/or during use (e.g. with the user being able to stretch and optionally flex the substrate).

In some embodiments, in the display area, the display substrate includes a plurality of islands Is and a plurality of bridges Br connecting the plurality of islands Is (discussed further in details below). A respective island of the plurality of islands Is includes at least one display element (e.g., at least one light emitting diode). The display substrate further includes a plurality of gaps G at least partially extending into (e.g., extending through) the display substrate. A respective gap of the plurality of gaps G is between adjacent islands of the plurality of islands Is.

In some embodiments, in the peripheral area, the display substrate also includes a plurality of second islands Is2 and a plurality of second bridges Br2 connecting the plurality of second islands Is2. A respective second island of the plurality of second islands Is2 includes at least one scan unit. The display substrate further includes a plurality of second gaps G2 at least partially extending into (e.g., extending through) the display substrate. A respective second gap of the plurality of second gaps G2 is between adjacent second islands of the plurality of second islands Is2.

Referring to FIG. 1 and FIG. 2, in some embodiments, the plurality of second gaps G2 are present in the second sub-area PA2 and the fourth sub-area PA4, and are absent in the first sub-area PA1 and the third sub-area PA3. The display substrate is stretchable in the second sub-area PA2 and the fourth sub-area PA4, and is less stretchable (e.g., non-stretchable) in the first sub-area PA1 and the third sub-area PA3.

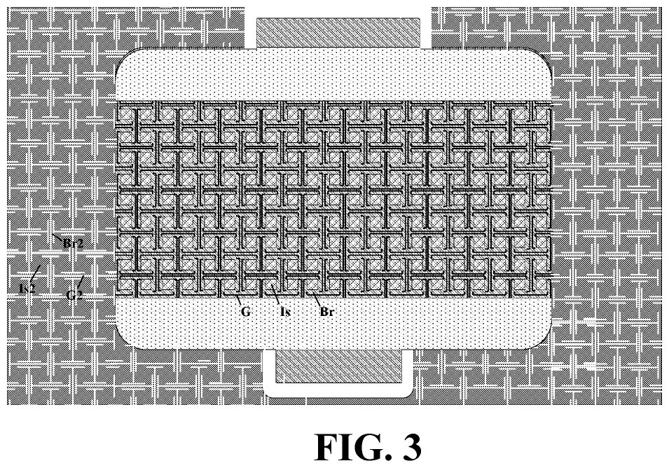

FIG. 3 is a schematic diagram illustrating the structure of a display substrate in some embodiments according to the present disclosure. Referring to FIG. 1 and FIG. 3, in some embodiments, the plurality of second gaps G2 are present in the first sub-area PA1, the second sub-area PA2, the third sub-area PA3, and the fourth sub-area PA4. The display substrate is at least partially stretchable in all four sub-areas, including the first sub-area PA1, the second sub-area PA2, the third sub-area PA3, and the fourth sub-area PA4.

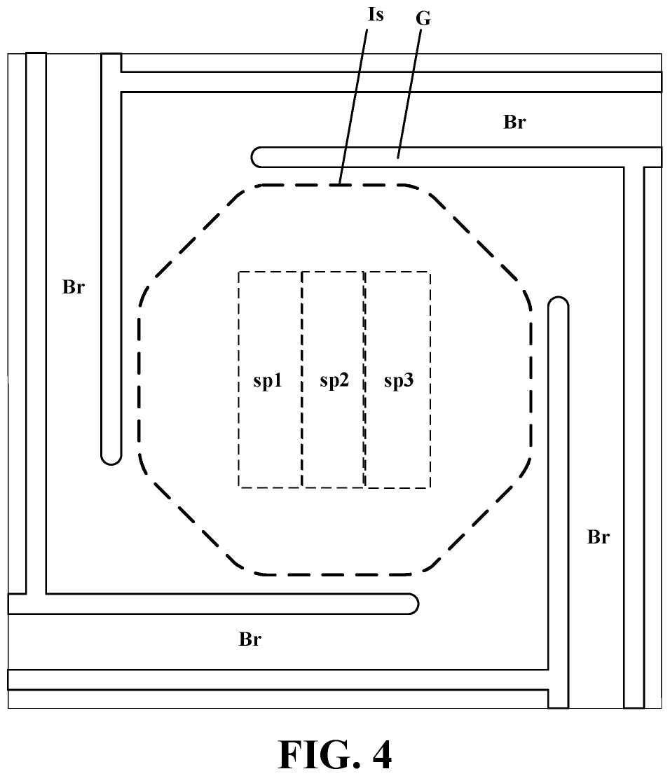

FIG. 4 is a schematic diagram illustrating a portion of a display area in a display substrate in some embodiments according to the present disclosure. FIG. 4 illustrates a respective island of the plurality of islands Is and four bridges of the plurality of bridges Br connected to the respective island. As shown in FIG. 4, a respective gap of the plurality of gaps G is between two adjacent islands and/or between a bridge and an island adjacent to each other.

In one example, the display substrate includes a single subpixel in the respective island.

In another example, the display substrate includes a plurality of subpixels in the respective island. In one particular example depicted in FIG. 4, the display substrate includes a first subpixel sp1 (e.g., a red subpixel), a second subpixel sp2 (e.g., a green subpixel), and a third subpixel sp3 (e.g., a blue subpixel). Each subpixel includes a display element (e.g., a light emitting diode).

Various appropriate pixel driving circuits may be used for driving light emission in the display elements in the display area. Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is a 7T1C driving circuit. Various appropriate light emitting elements may be used in the present display substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

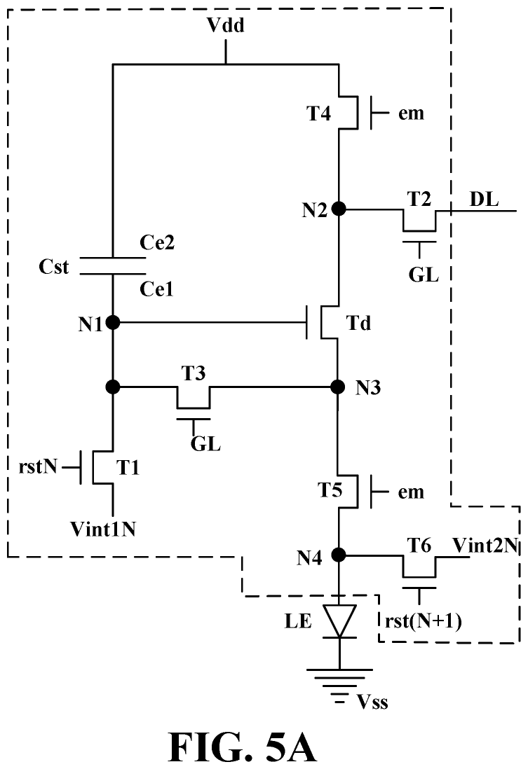

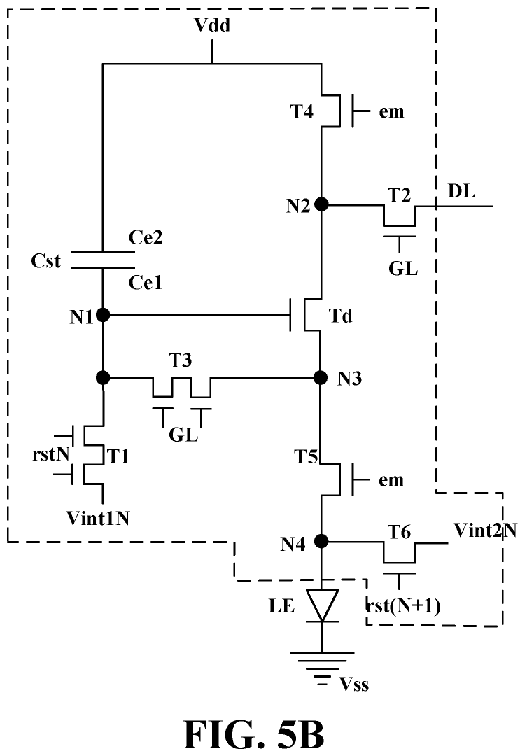

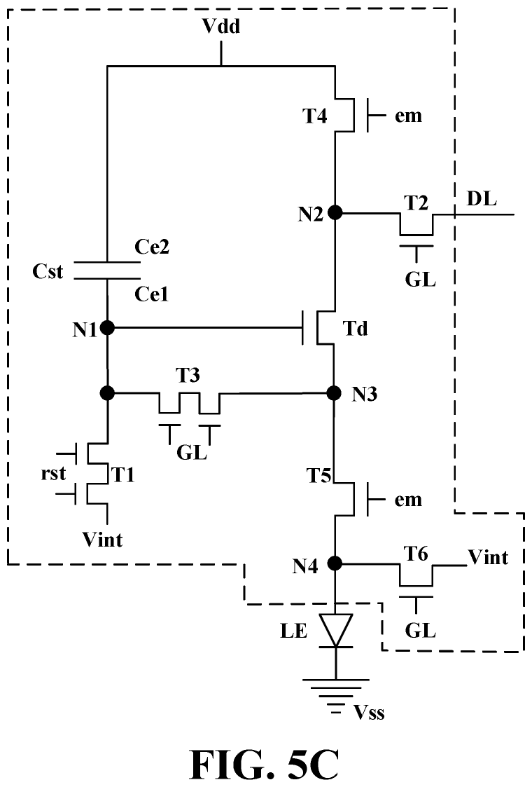

FIG. 5A is a circuit diagram illustrating the structure of a pixel driving circuit in some embodiments according to the present disclosure. Referring to FIG. 5A, in some embodiments, the respective pixel driving circuit includes a driving transistor Td; a storage capacitor Cst having a first capacitor electrode Ce1 and a second capacitor electrode Ce2; a first transistor T1 having a gate electrode connected to a respective reset control signal line rstN in a present stage (or a present row) of a plurality of reset control signal lines, a first electrode connected to a respective first reset signal line Vint1N in a present stage (or a present row) of a plurality of first reset signal lines, and a second electrode connected to a first capacitor electrode Ce1 of the storage capacitor Cst and a gate electrode of the driving transistor Td; a second transistor T2 having a gate electrode connected to a respective gate line of a plurality of gate lines GL, a first electrode connected to a respective data line of a plurality of data lines DL, and a second electrode connected to a first electrode of the driving transistor Td; a third transistor T3 having a gate electrode connected to the respective gate line, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective voltage supply line of a plurality of voltage supply lines Vdd, and a second electrode connected to the first electrode of the driving transistor Td and the second electrode of the second transistor T2; a fifth transistor T5 having a gate electrode connected to the respective light emitting control signal line, a first electrode connected to second electrodes of the driving transistor Td and the third transistor T3, and a second electrode connected to an anode of a light emitting element LE; and a sixth transistor T6 having a gate electrode connected to a respective reset control signal line rst (N+1) in a next adjacent stage (or a next adjacent row) of a plurality of reset control signal lines, a first electrode connected to a respective second reset signal line Vint2N in the present stage (or the present row) of the plurality of second reset signal lines, and a second electrode connected to the second electrode of the fifth transistor and the anode of the light emitting element LE. The second capacitor electrode Ce2 is connected to the respective voltage supply line and the first electrode of the fourth transistor T4.

FIG. 5B is a circuit diagram illustrating the structure of a pixel driving circuit in some embodiments according to the present disclosure. Referring to FIG. 5B, in some embodiments, the third transistor T3 is a “double gate” transistor, and the first transistor T1 is a “double gate” transistor. Optionally, in a “double gate” first transistor, the active layer of the first transistor crosses over a respective reset control signal lines twice (alternatively, the respective reset control signal line crosses over the active layer of the first transistor T1 twice). Similarly, in a “double gate” third transistor, the active layer of the third transistor T3 crosses over a respective gate line of the plurality of gate lines GL twice (alternatively, the respective gate line crosses over the active layer of the third transistor T3 twice).

The pixel driving circuit further include a first node N1, a second node N2, a third node N3, and a fourth node N4. The first node N1 is connected to the gate electrode of the driving transistor Td, the first capacitor electrode Ce1, and the first electrode of the third transistor T3. The second node N2 is connected to the second electrode of the fourth transistor T4, the second electrode of the second transistor T2, and the first electrode of the driving transistor Td. The third node N3 is connected to the second electrode of the driving transistor Td, the second electrode of the third transistor T3, and the first electrode of the fifth transistor T5. The fourth node N4 is connected to the second electrode of the fifth transistor T5, the second electrode of the sixth transistor T6, and the anode of the light emitting element LE.

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

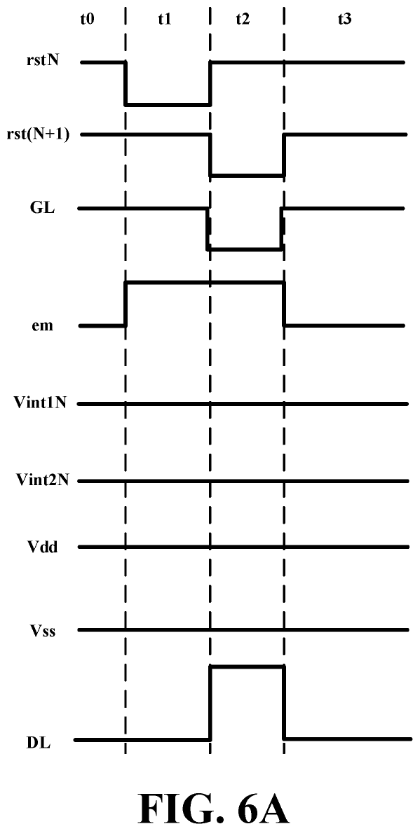

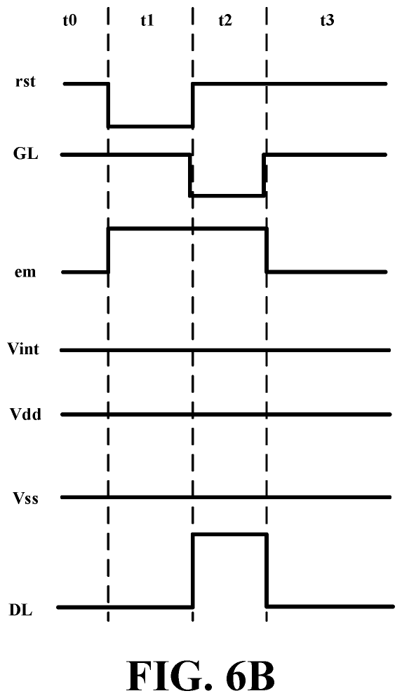

FIG. 6A is a timing diagram illustrating the operation of a pixel driving circuit in some embodiments according to the present disclosure. Referring to FIG. 5A, FIG. 5B, and FIG. 6A, during one frame of image, the operation of the pixel driving circuit includes a reset sub-phase t1, a data write sub-phase t2, and a light emitting sub-phase t3. In the initial sub-phase t0, a turning-off reset control signal is provided through the reset control signal line of a present stage rstN to the gate electrode of the first transistor T1 to turn off the first transistor T1. In the initial sub-phase t0, the gate line GL is provided with a turning-off signal, thus the second transistor T2 and the third transistor T3 are turned off.

In the reset sub-phase t1, a turning-on reset control signal is provided through the reset control signal line of a present stage rstN to the gate electrode of the first transistor T1 to turn on the first transistor T1; allowing an initialization voltage signal from the respective first reset signal line of a present stage Vint1N to pass from a first electrode of the first transistor T1 to a second electrode of the first transistor T1, and in turn to the first capacitor electrode Ce1 and the gate electrode of the driving transistor Td. The gate electrode of the driving transistor Td is initialized. The second capacitor electrode Ce2 receives a high voltage signal from the respective voltage supply line of the plurality of voltage supply lines Vdd. The first capacitor electrode Ce1 is charged in the reset sub-phase t1 due to an increasing voltage difference between the first capacitor electrode Ce1 and the second capacitor electrode Ce2. In the reset sub-phase t1, the respective gate line of the plurality of gate lines GL is provided with a turning-off signal, thus the second transistor T2 and the third transistor T3 are turned off. The respective light emitting control signal line of the plurality of light emitting control signal lines em is provided with a high voltage signal to turn off the fourth transistor T4 and the fifth transistor T5.

In the data write sub-phase t2, the turning-off reset control signal is again provided through the reset control signal line of a present stage rstN to the gate electrode of the first transistor T1 to turn off the first transistor T1. The respective gate line of the plurality of gate lines GL is provided with a turning-on signal, thus the second transistor T2 and the third transistor T3 are turned on. A second electrode of the driving transistor Td is connected with the second electrode of the third transistor T3. A gate electrode of the driving transistor Td is electrically connected with the first electrode of the third transistor T3. Because the third transistor T3 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The second transistor T2 is turned on in the data write sub-phase t2. The data voltage signal transmitted through the respective data line of a plurality of data lines DL is received by a first electrode of the second transistor T2, and in turn transmitted to the first electrode of the driving transistor Td, which is connected to the second electrode of the second transistor T2. A node N2 connecting to the first electrode of the driving transistor Td has a voltage level of the data voltage signal. Because only the PN junction between the gate electrode and a first electrode of the driving transistor Td is effective, the voltage level at the node N1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line of the plurality of light emitting control signal lines em is provided with a high voltage signal to turn off the fourth transistor T4 and the fifth transistor T5.

In the data write sub-phase t2, a turning-on reset control signal is provided through the respective reset control signal line rst (N+1) in a next adjacent stage to the gate electrode of the sixth transistor T6 to turn on the sixth transistor T6; allowing an initialization voltage signal from the respective second reset signal line of a present stage Vint2N to pass from a first electrode of the sixth transistor T6 to a second electrode of the sixth transistor T6; and in turn to the node N4. The anode of the light emitting element LE is initialized.

In the light emitting sub-phase t3, the turning-off reset control signal is again provided through the reset control signal line of a present stage rstN to the gate electrode of the first transistor T1 to turn off the first transistor T1. The respective gate line of the plurality of gate lines GL is provided with a turning-off signal, the second transistor T2 and the third transistor T3 are turned off. The respective light emitting control signal line of the plurality of light emitting control signal lines em is provided with a low voltage signal to turn on the fourth transistor T4 and the fifth transistor T5. The voltage level at the node N1 in the light emitting sub-phase t3 is maintained at (Vdata+Vth), the driving transistor Td is turned on by the voltage level, and working in the saturation area. A path is formed through the fourth transistor T4, the driving transistor Td, the fifth transistor T5, to the light emitting element LE. The driving transistor Td generates a driving current for driving the light emitting element LE to emit light. A voltage level at a node N3 connected to the second electrode of the driving transistor Td equals to a light emitting voltage of the light emitting element LE.

FIG. 5C is a circuit diagram illustrating the structure of a pixel driving circuit in some embodiments according to the present disclosure. Referring to FIG. 5C, in some embodiments, the respective pixel driving circuit includes a driving transistor Td; a storage capacitor Cst having a first capacitor electrode Ce1 and a second capacitor electrode Ce2; a first transistor T1 having a gate electrode connected to a respective reset control signal line of a plurality of reset control signal lines rst, a first electrode connected to a respective reset signal line of a plurality of first reset signal lines Vint, and a second electrode connected to a first capacitor electrode Ce1 of the storage capacitor Cst and a gate electrode of the driving transistor Td; a second transistor T2 having a gate electrode connected to a respective gate line of a plurality of gate lines GL, a first electrode connected to a respective data line of a plurality of data lines DL, and a second electrode connected to a first electrode of the driving transistor Td; a third transistor T3 having a gate electrode connected to the respective gate line, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective voltage supply line of a plurality of voltage supply lines Vdd, and a second electrode connected to the first electrode of the driving transistor Td and the second electrode of the second transistor T2; a fifth transistor T5 having a gate electrode connected to the respective light emitting control signal line, a first electrode connected to second electrodes of the driving transistor Td and the third transistor T3, and a second electrode connected to an anode of a light emitting element LE; and a sixth transistor T6 having a gate electrode connected to the respective gate line of the plurality of gate lines GL, a first electrode connected to the respective reset signal line of the plurality of first reset signal lines Vint, and a second electrode connected to the second electrode of the fifth transistor and the anode of the light emitting element LE. The second capacitor electrode Ce2 is connected to the respective voltage supply line and the first electrode of the fourth transistor T4. FIG. 6B is a timing diagram illustrating the operation of a pixel driving circuit in some embodiments according to the present disclosure. FIG. 6B illustrates the operation of the pixel driving circuit depicted in FIG. 5C.

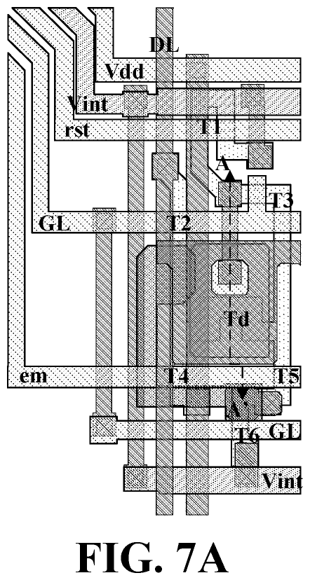

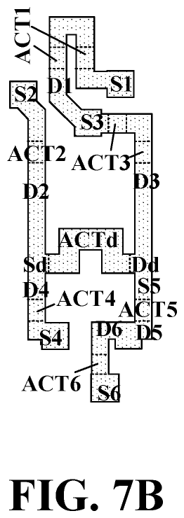

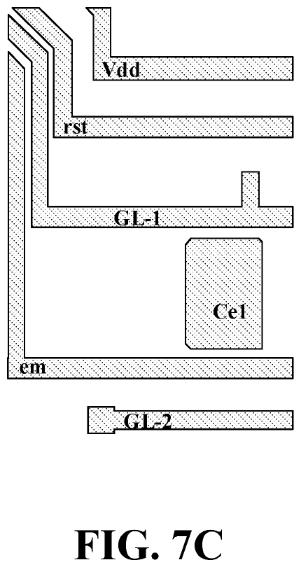

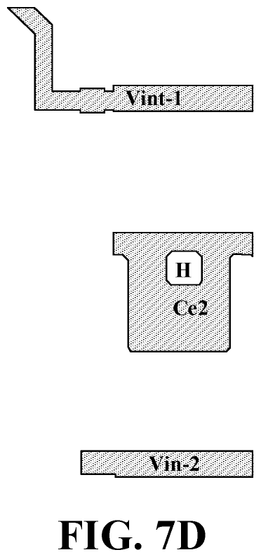

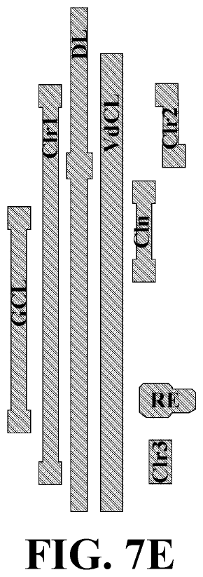

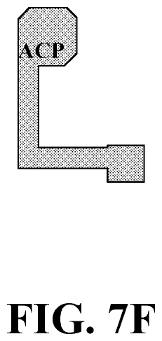

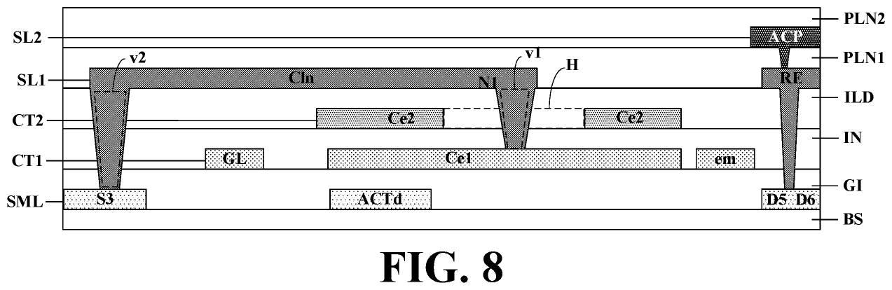

FIG. 7A is a diagram illustrating the structure of the structure of a display substrate in some embodiments according to the present disclosure. FIG. 7B is a diagram illustrating the structure of a semiconductor material layer in the display substrate depicted in FIG. 7A. FIG. 7C is a diagram illustrating the structure of a first conductive layer in the display substrate depicted in FIG. 7A. FIG. 7D is a diagram illustrating the structure of a second conductive layer in the display substrate depicted in FIG. 7A. FIG. 7E is a diagram illustrating the structure of a first signal line layer in the display substrate depicted in FIG. 7A. FIG. 7F is a diagram illustrating the structure of a second signal line layer in the display substrate depicted in FIG. 7A. FIG. 8 is a cross-sectional view along an A-A′ line in FIG. 7A. In one example, FIG. 3A to FIG. 3F, and FIG. 8 depict a pixel driving circuit configured to driving light emission in the first subpixel sp1 depicted in FIG. 4.

FIG. 7A illustrates the structures of several layers of the display substrate, including a semiconductor material layer, a first conductive layer, a second conductive layer, a first signal line layer, and a second signal line layer. Corresponding positions of the plurality of transistors in the pixel driving circuit are depicted in FIG. 7A. The pixel driving circuit in some embodiments includes the first transistor T1, the second transistor T2, the third transistor T3, the fourth transistor T4, the fifth transistor T5, the sixth transistor T6, and the driving transistor Td.

Referring to FIG. 3A to FGI. 7F, and FIG. 8, in some embodiments, the display substrate includes a base substrate BS, a semiconductor material layer SML on the base substrate BS, a gate insulating layer GI on a side of the semiconductor material layer SML away from the base substrate BS, a first conductive layer CT1 on a side of the gate insulating layer GI away from the semiconductor material layer SML, an insulating layer IN on a side of the first conductive layer away from the gate insulating layer GI, a second conductive layer CT2 on a side of the insulating layer IN away from the first conductive layer CT1, an inter-layer dielectric layer ILD on a side of the second conductive layer CT2 away from the insulating layer IN, a first signal line layer SL1 on a side of the inter-layer dielectric layer ILD away from the second conductive layer CT2, a first planarization layer PLN1 on a side of the first signal line layer SL1 away from the inter-layer dielectric layer ILD, a second signal line layer SL2 on a side of the first planarization layer PLN1 away from the first signal line layer SL1, and a second planarization layer PLN2 on a side of the second signal line layer SL2 away from the first planarization layer PLN1.

Referring to FIG. 7A, the display substrate in some embodiments includes a respective gate line of a plurality of gate lines GL, a respective reset control signal line of a plurality of reset control signal lines rst; a respective reset signal line of a plurality of reset signal lines Vint; a respective light emitting control signal line of a plurality of light emitting control signal lines em; a respective voltage supply line of a plurality of voltage supply lines Vdd; and a respective data line of a plurality of data lines DL.

Referring to FIG. 7A and FIG. 7B, a respective pixel driving circuit is annotated with labels indicating regions corresponding to the plurality of transistors in the respective pixel driving circuit, including the first transistor T1, the second transistor T2, the third transistor T3, the fourth transistor T4, the fifth transistor T5, the sixth transistor T6, and the driving transistor Td. The respective pixel driving circuit is further annotated with labels indicating components of each of the plurality of transistors in the pixel driving circuit. For example, the first transistor T1 includes an active layer ACT1, a first electrode S1, and a second electrode D1. The second transistor T2 includes an active layer ACT2, a first electrode S2, and a second electrode D2. The third transistor T3 includes an active layer ACT3, a first electrode S3, and a second electrode D3. The fourth transistor T4 includes an active layer ACT4, a first electrode S4, and a second electrode D4. The fifth transistor T5 includes an active layer ACT5, a first electrode S5, and a second electrode D5. The sixth transistor T6 includes an active layer ACT6, a first electrode S6, and a second electrode D6. The driving transistor Td includes an active layer ACTd, a first electrode Sd, and a second electrode Dd. In one example, the active layers (ACT1, ACT2, ACT3, ACT4, ACT5, ACT6, and ACTd) of the transistors (T1, T2, T3, T4, T5, T6, and Td) in the respective pixel driving circuit are parts of a unitary structure. In another example, the active layers (ACT1, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) in the respective pixel driving circuit are parts of a unitary structure. In another example, the active layers (ACT1, ACT2, ACT3, ACT4, ACT5, ACT6, and ACTd) of the transistors (T1, T2, T3, T4, T5, T6, and Td) are in a same layer. In another example, the active layers (ACT1, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) are in a same layer.

As used herein, the term “same layer” refers to the relationship between the layers simultaneously formed in the same step. In one example, the active layers, the first electrodes, and the second electrodes are in a same layer when they are formed as a result of one or more steps of a same patterning process performed in a same layer of material. In another example, the active layers, the first electrodes, and the second electrodes can be formed in a same layer by simultaneously performing the step of forming the active layers, the step of forming the first electrodes, and the step of forming the second electrodes. The term “same layer” does not always mean that the thickness of the layer or the height of the layer in a cross-sectional view is the same.

As used herein, the active layer refers to a component of the transistor comprising at least a portion of the semiconductor material layer whose orthographic projection on the base substrate overlaps with an orthographic projection of a gate electrode on the base substrate. As used herein, a first electrode refers to a component of the transistor connected to one side of the active layer, and a second electrode refers to a component of the transistor connected to another side of the active layer. In the context of a double-gate type transistor (for example, the third transistor T3), the active layer refers to a component of the transistor comprising a first portion of the semiconductor material layer whose orthographic projection on the base substrate overlaps with an orthographic projection of a first gate on the base substrate, a second portion of the semiconductor material layer whose orthographic projection on the base substrate overlaps with an orthographic projection of a second gate on the base substrate, and a third portion between the first portion and the second portion. In the context of a double-gate type transistor, a first electrode refers to a component of the transistor connected to a side of the first portion distal to the third portion, and a second electrode refers to a component of the transistor connected to a side of the second portion distal to the third portion.

Referring to FIG. 7A and FIG. 7C, the first conductive layer in some embodiments includes a respective gate line of the plurality of gate lines GL, a respective reset control signal line of the plurality of reset control signal lines rst, a respective light emitting control signal line of the plurality of light emitting control signal lines em, a respective voltage supply line of a plurality of voltage supply lines Vdd, and a first capacitor electrode Ce1 of the storage capacitor Cst. Various appropriate electrode materials and various appropriate fabricating methods may be used to make the first conductive layer. For example, a conductive material may be deposited on the substrate by a plasma-enhanced chemical vapor deposition (PECVD) process and patterned. Examples of appropriate conductive materials for making the first conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

In some embodiments, the respective gate line in the respective island includes a first gate branch line GL-1 and a second gate branch line GL-2. Referring to FIG. 7A, FIG. 7C, and FIG. 7E, in some embodiment, the first gate branch line GL-1 and the second gate branch line GL-2 are connected by one or more gate connecting lines GCL. In one example, the first gate branch line GL-1 and the second gate branch line GL-2 are in the first conductive layer, and the one or more gate connecting lines GCL are in the first signal line layer. The first gate branch line GL-1 is configured to provide a gate scanning signal to the second transistor T2 and the third transistor T3. The second gate branch line GL-2 is configured to provide a gate scanning signal to the sixth transistor T6.

Referring to FIG. 7A and FIG. 7D, the second conductive layer in some embodiments includes a respective reset signal line of the plurality of reset signal lines Vint and a second capacitor electrode Ce2 of the storage capacitor Cst. Various appropriate conductive materials and various appropriate fabricating methods may be used to make the second conductive layer. For example, a conductive material may be deposited on the substrate by a plasma-enhanced chemical vapor deposition (PECVD) process and patterned. Examples of appropriate conductive materials for making the second conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the respective reset signal line of the plurality of reset signal lines Vint and a second capacitor electrode Ce2 are in a same layer.

In some embodiments, the respective reset signal line in the respective island includes a first reset signal branch line Vint-1 and a second reset signal branch line Vint-2. Referring to FIG. 7A, FIG. 7C, and FIG. 7E, in some embodiment, the first reset signal branch line Vint-1 and the second reset signal branch line Vint-2 are connected by one or more first reset signal connecting lines Clr1. In one example, the first reset signal branch line Vint-1 and the second reset signal branch line Vint-2 are in the second conductive layer, and the one or more first reset signal connecting lines Clr1 is in the first signal line layer. The first reset signal branch line Vint-1 is configured to provide a reset signal to the first transistor T1. The second reset signal branch line Vint-2 is configured to provide a reset signal to the sixth transistor T6.

Referring to FIG. 7A and FIG. 7E, the first signal line layer in some embodiments includes a node connecting line Cln, one or more first reset signal connecting lines Clr1, a second reset signal connecting line Clr2, a third reset signal connecting line Clr3, one or more gate connecting lines GCL, a respective data line of the plurality of data lines DL, a relay electrode RE, and one or more voltage supply connecting lines VdCL. The node connecting line Cln connects the first capacitor electrode Ce1 and the source electrode of the third transistor T3 in a respective pixel driving circuit together. The relay electrode RE connects the node N4 and an anode connecting pad together. The node N4 is connected to drain electrodes of the fifth transistor T5 and the sixth transistor T6. The anode connecting pad is in the second signal line layer, and is connected to a respective anode in a respective light emitting element. The one or more first reset signal connecting lines Clr1 connects the first reset signal branch line Vint-1 to the second reset signal branch line Vint-2. The one or more voltage supply connecting lines VdCL connects a respective voltage supply line of a plurality of voltage supply lines to a first electrode of the fourth transistor T4. The second reset signal connecting line Clr2 connects the first reset signal branch line Vint-1 to a first electrode of the first transistor T1. The third reset signal connecting line Clr3 connects the second reset signal branch line Vint-2 to a first electrode of the sixth transistor T6.

Referring to FIG. 7A to FIG. 7F, and FIG. 8, in some embodiments, an orthographic projection of the second capacitor electrode Ce2 on a base substrate BS completely covers, with a margin, an orthographic projection of the first capacitor electrode Ce1 on the base substrate BS except for a hole region H in which a portion of the second capacitor electrode Ce2 is absent. In some embodiments, the first signal line layer includes a node connecting line Cln on a side of the inter-layer dielectric layer ILD away from the second capacitor electrode Ce2. The node connecting line Cln is in a same layer as the one or more first reset signal connecting lines Clr1, the second reset signal connecting line Clr2, the third reset signal connecting line Clr3, the one or more gate connecting lines GCL, the respective data line of the plurality of data lines DL, the relay electrode RE, and the one or more voltage supply connecting lines VdCL.

In some embodiments, the first capacitor electrode Ce1 is on a side of the gate insulating layer GI away from the base substrate BS. Optionally, the display substrate further includes a first via v1 and a second via v2. The first via v1 is in the hole region H and extends through the inter-layer dielectric layer ILD and the insulating layer IN. The second via v2 extends through the inter-layer dielectric layer ILD, the insulating layer IN, and the gate insulating layer GI. Optionally, the node connecting line Cln is connected to the first capacitor electrode Ce1 through the first via v1, and the node connecting line Cln is connected to the semiconductor material layer SML through the second via v2. Optionally, the node connecting line Cln is connected to the source electrode S3 of third transistor, as depicted in FIG. 8.

Referring to Referring to FIG. 7A and FIG. 7F, the second signal line layer in some embodiments includes an anode contact pad ACP. The anode contact pad ACP is electrically connected to a source electrode of the fifth transistor T5 in the respective pixel driving circuit through a relay electrode. The anode contact pad ACP is electrically connected to an anode in a respective light emitting element.

Various appropriate conductive materials and various appropriate fabricating methods may be used to make the first signal line layer and the second signal line layer. For example, a conductive material may be deposited on the substrate by a plasma-enhanced chemical vapor deposition (PECVD) process and patterned. Examples of appropriate conductive materials for making the first signal line layer or the second signal line layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

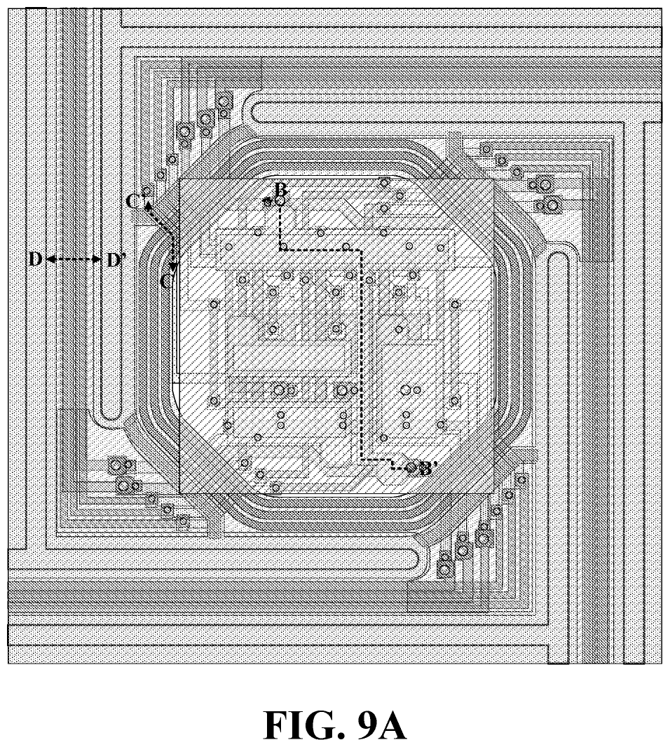

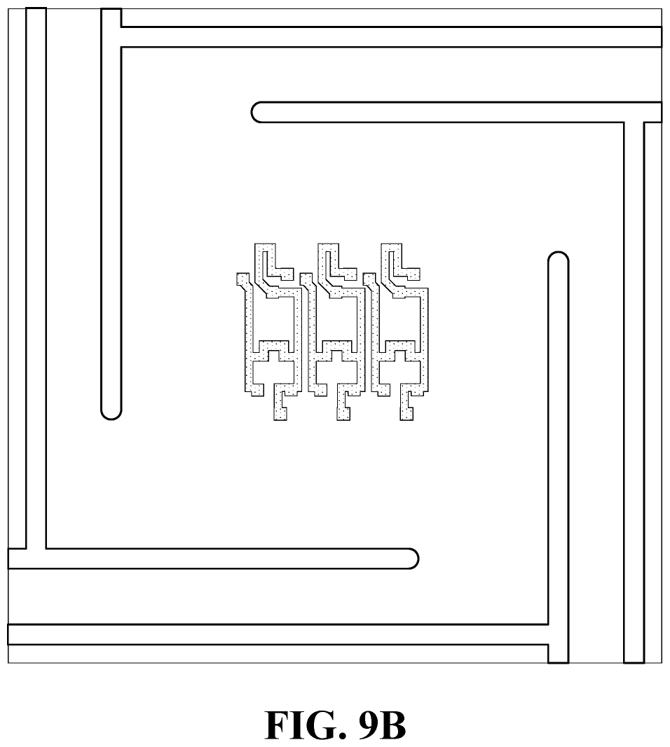

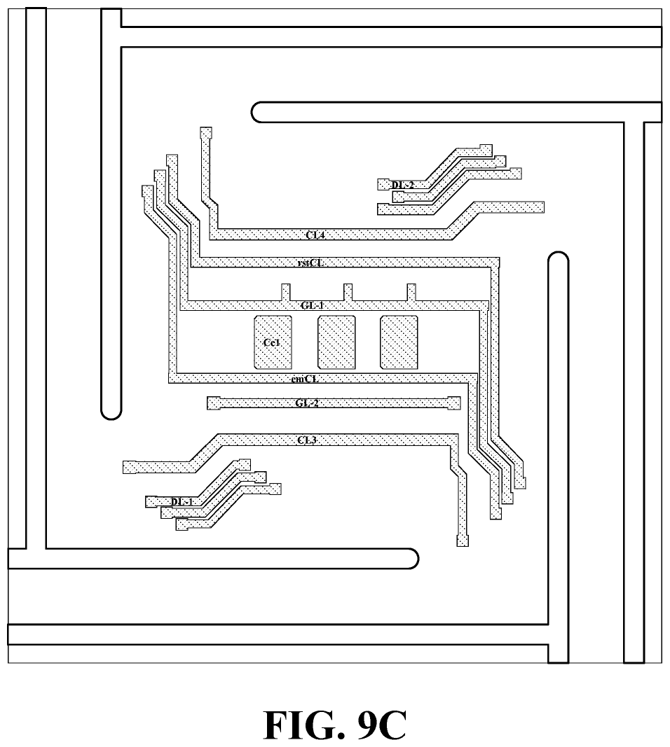

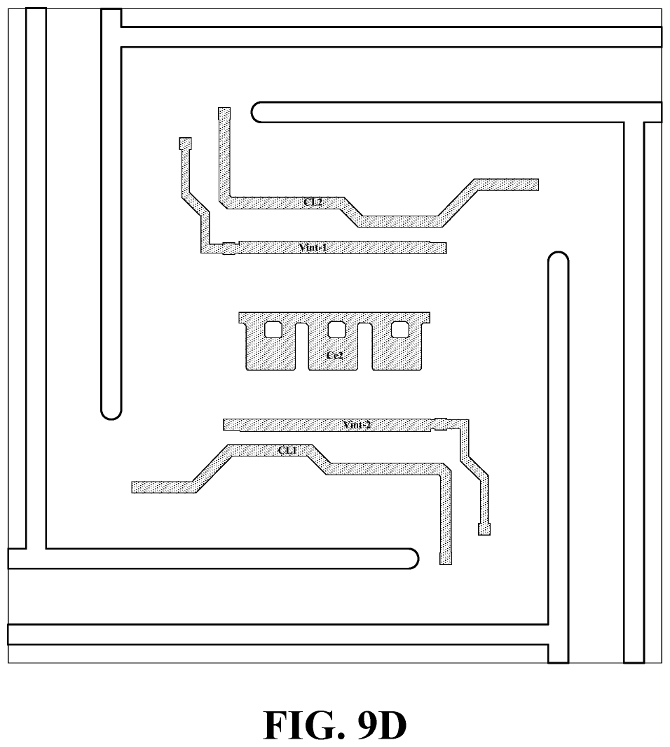

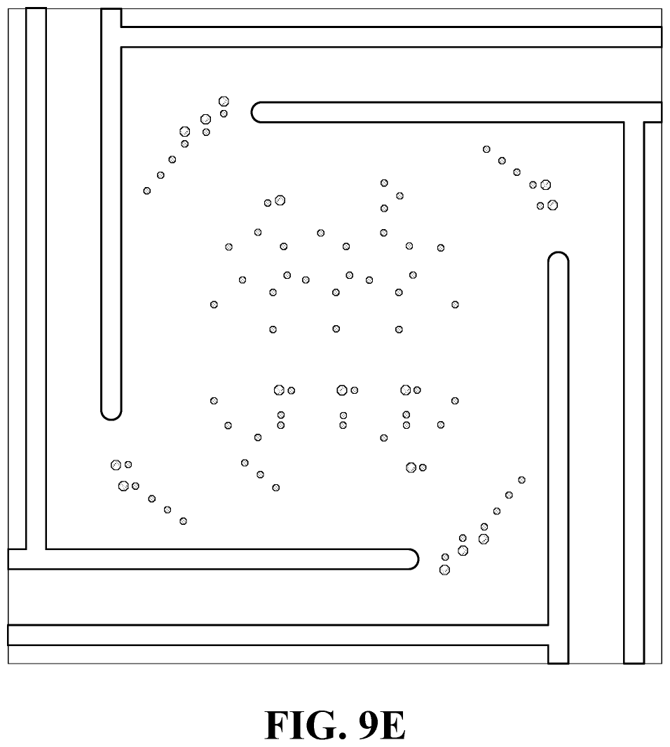

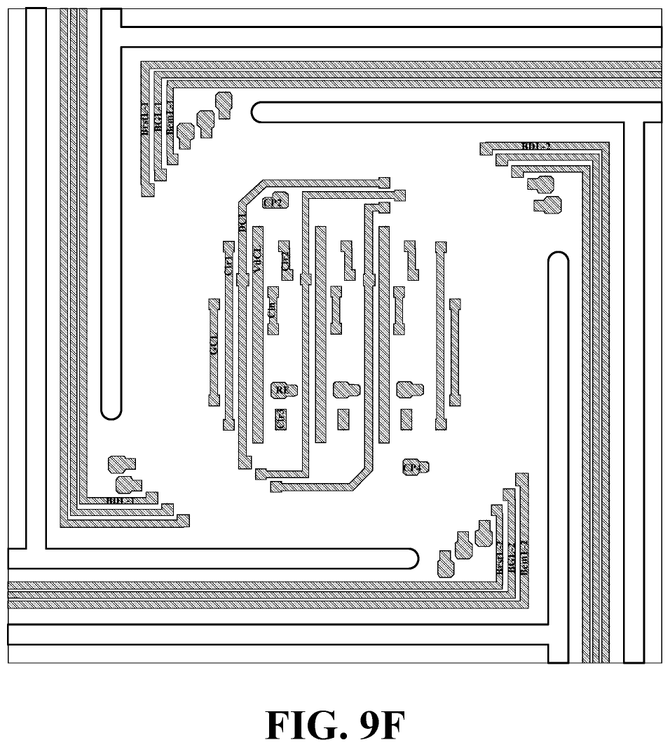

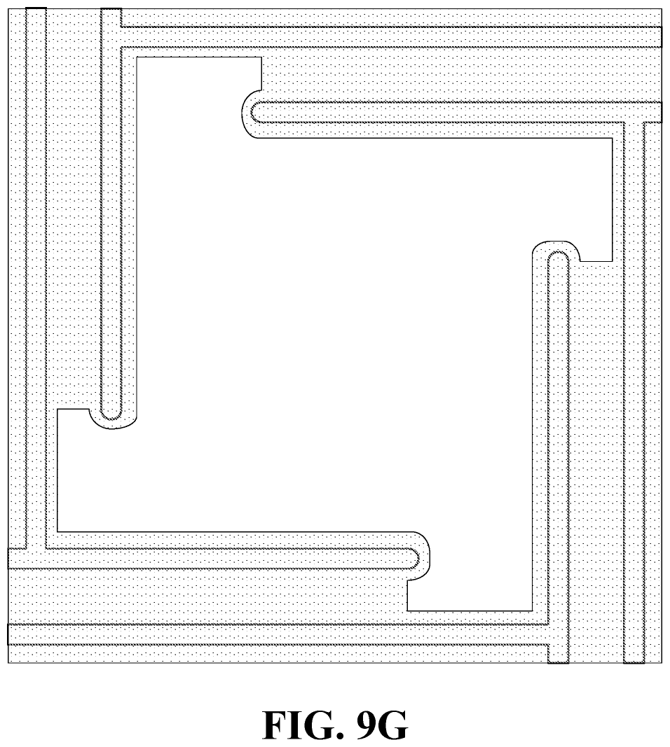

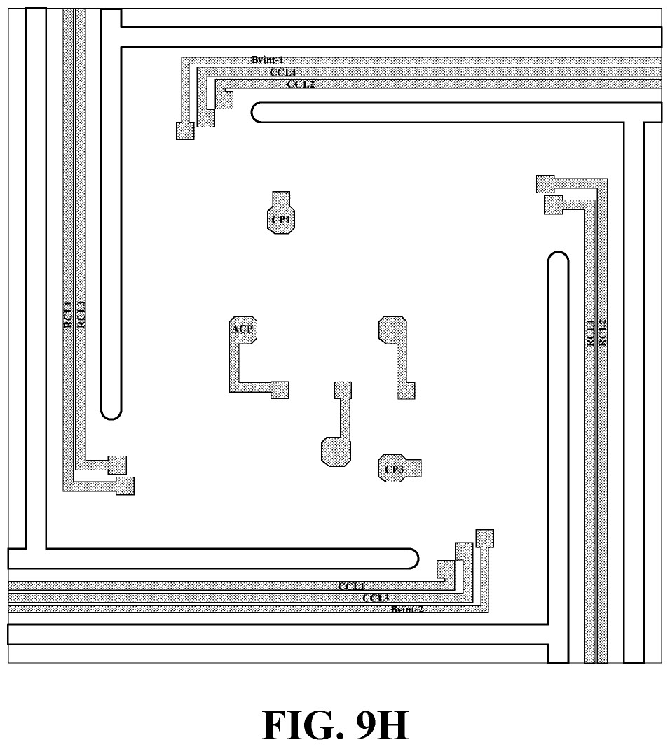

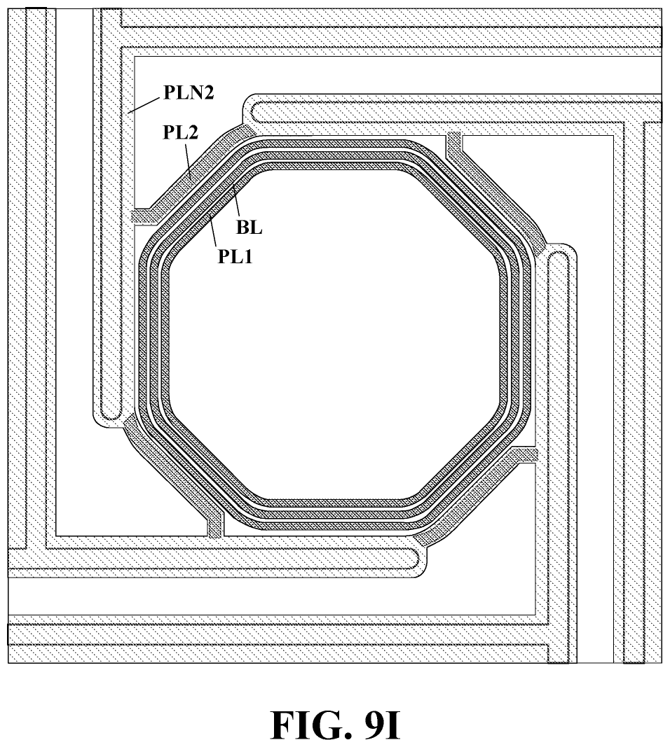

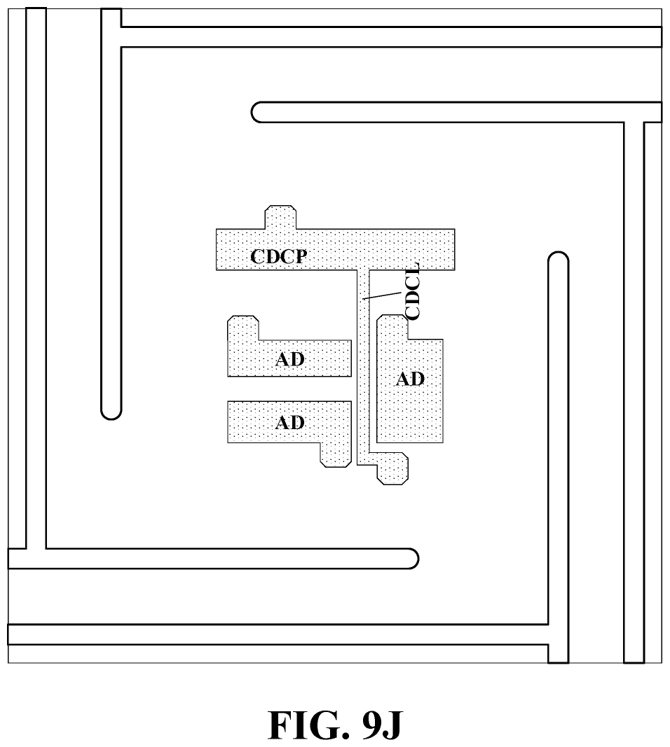

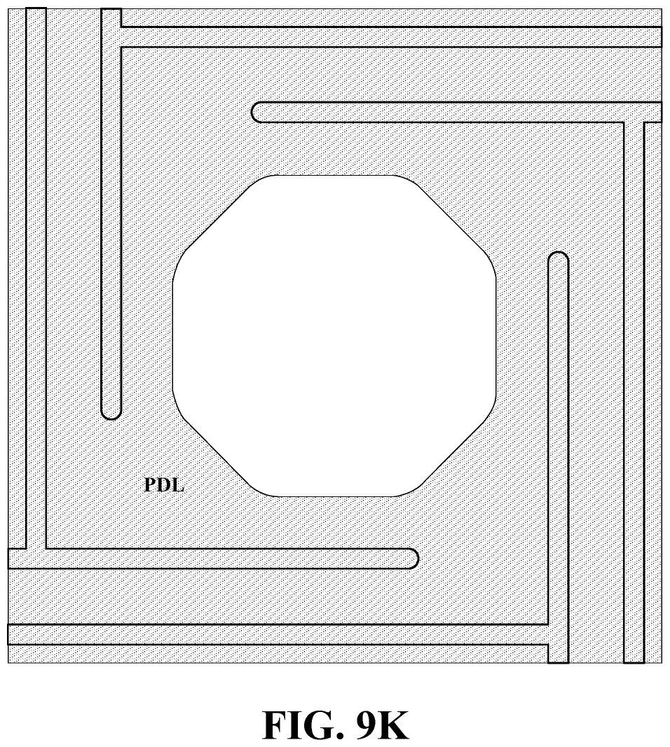

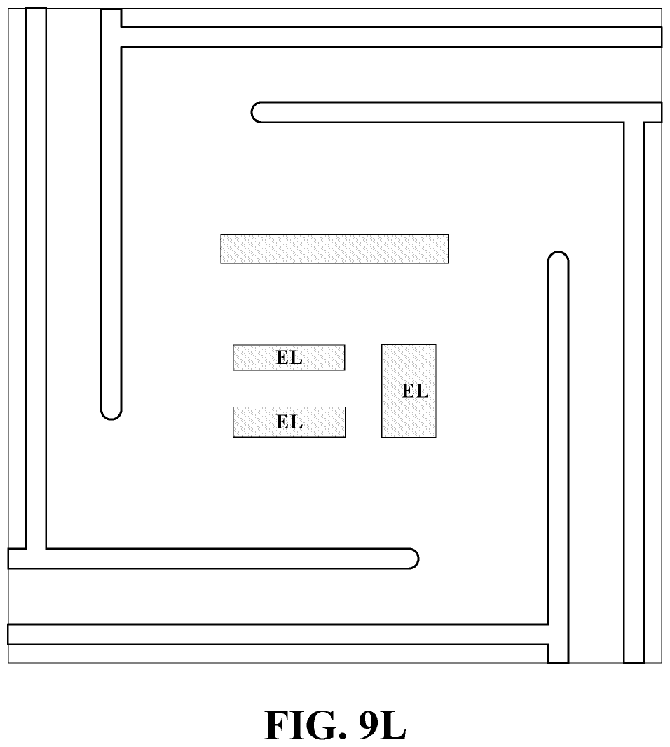

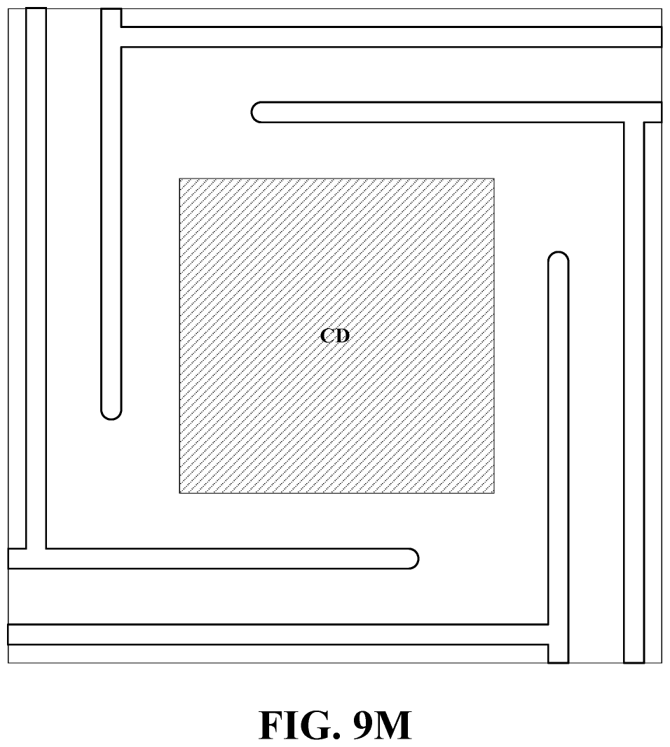

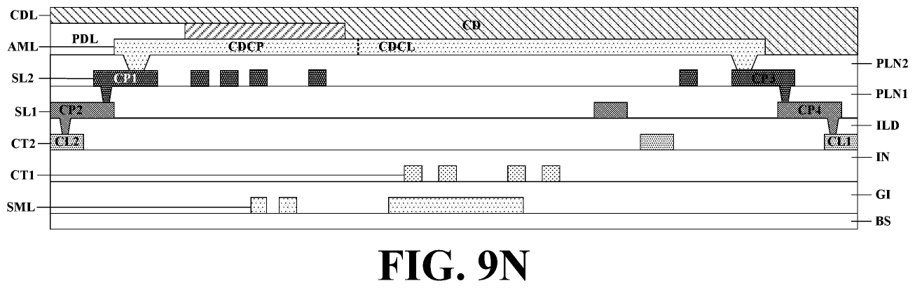

FIG. 9A is a schematic diagram illustrating the structure of a portion of a display area in a display substrate in some embodiments according to the present disclosure. FIG. 9B is a diagram illustrating the structure of a semiconductor material layer in the display substrate depicted in FIG. 9A. FIG. 9C is a diagram illustrating the structure of a first conductive layer in the display substrate depicted in FIG. 9A. FIG. 9D is a diagram illustrating the structure of a second conductive layer in the display substrate depicted in FIG. 9A. FIG. 9E is a diagram illustrating the structure of an inter-layer dielectric layer in the display substrate depicted in FIG. 9A. FIG. 9F is a diagram illustrating the structure of a first signal line layer in the display substrate depicted in FIG. 9A. FIG. 9G is a diagram illustrating the structure of a first planarization layer in the display substrate depicted in FIG. 9A. FIG. 9H is a diagram illustrating the structure of a second signal line layer in the display substrate depicted in FIG. 9A. FIG. 9I is a diagram illustrating the structure of a second planarization layer in the display substrate depicted in FIG. 9A. FIG. 9J is a diagram illustrating the structure of an anode material layer in the display substrate depicted in FIG. 9A. FIG. 9K is a diagram illustrating the structure of a pixel definition layer in the display substrate depicted in FIG. 9A. FIG. 9L is a diagram illustrating the structure of a light emitting layer in the display substrate depicted in FIG. 9A. FIG. 9M is a diagram illustrating the structure of a cathode material layer in the display substrate depicted in FIG. 9A. FIG. 9N is a cross-sectional view along a B-B′ line in FIG. 9A. The portion of the display area of the display substrate depicted in FIG. 9A to FIG. 9N corresponds to the portion of the display area of the display substrate depicted in FIG. 4. FIG. 9A to FIG. 9N illustrate the structure of three subpixels sp1, sp2, and sp3, including the layout of three pixel driving circuits configured to drive light emission in the three subpixels sp1, sp2, and sp3 in a respective island of the plurality of islands. The structure of the pixel driving circuit configured to drive light emission in the subpixel sp1 is depicted in FIG. 7A to FIG. 7E. The structures of the pixel driving circuits configured to drive light emission in the subpixels sp2 and sp3 are similar to the structure of the pixel driving circuit configured to drive light emission in the subpixel sp1. The relative arrangement and signal line layout among the three subpixels sp1, sp2, and sp3 are depicted in FIG. 9A to FIG. 9N.

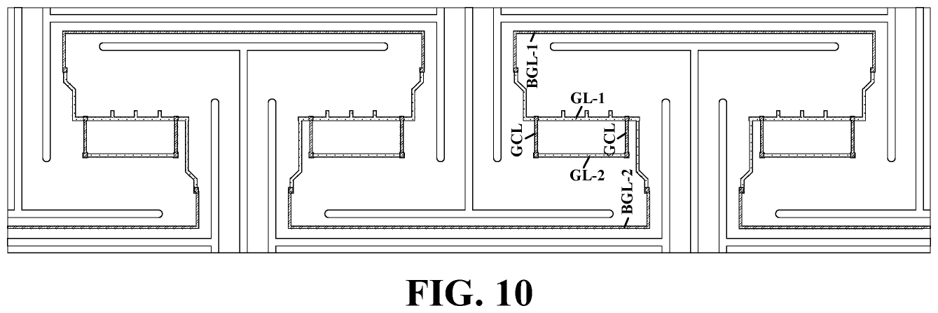

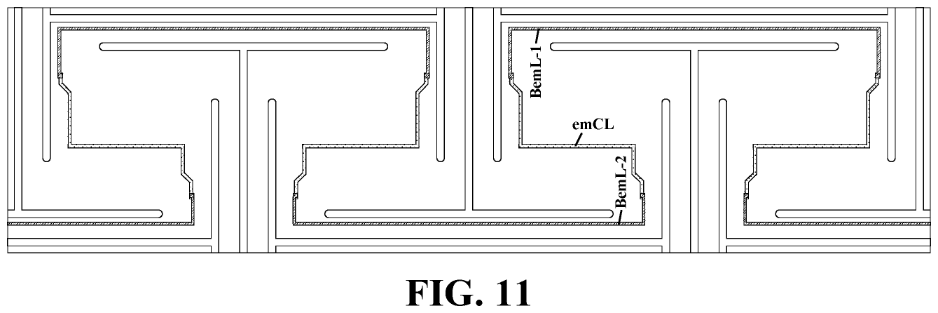

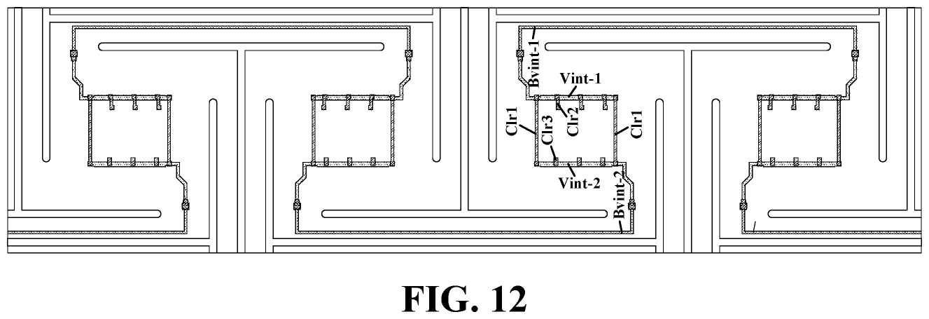

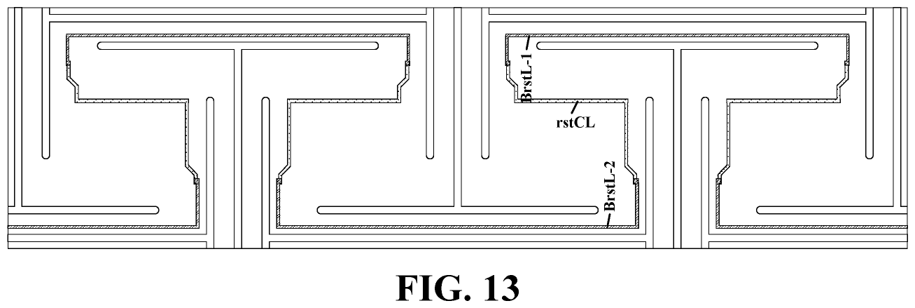

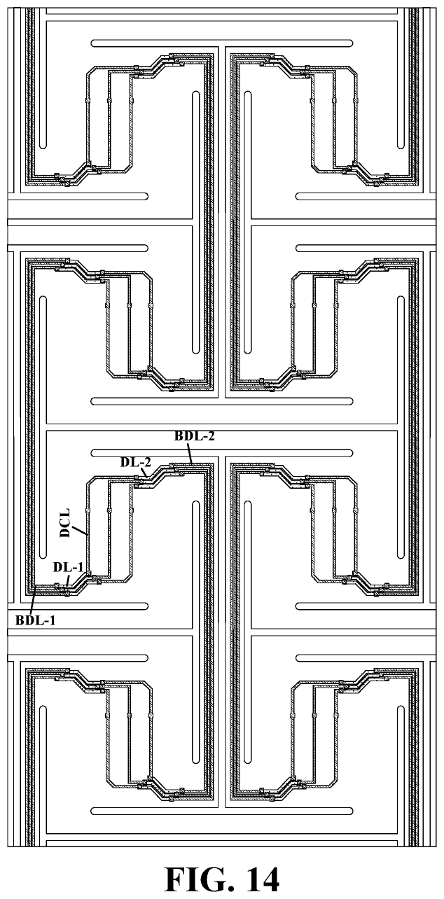

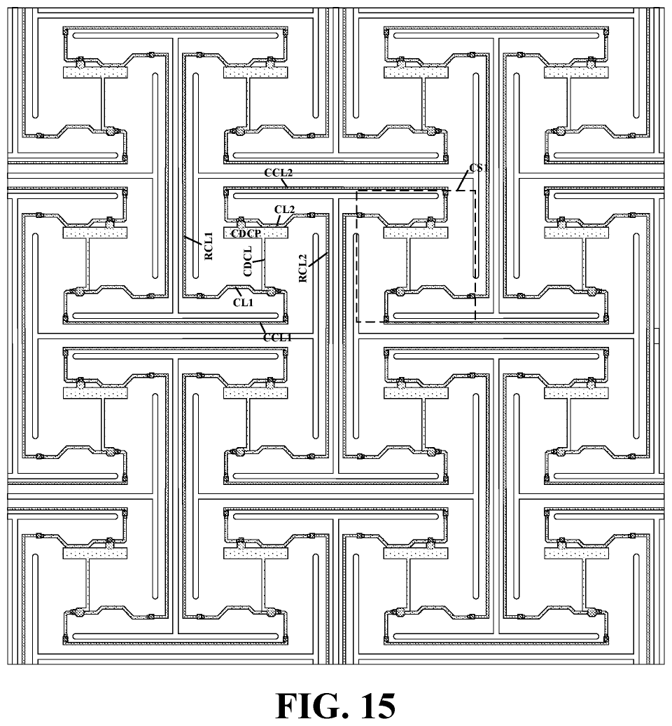

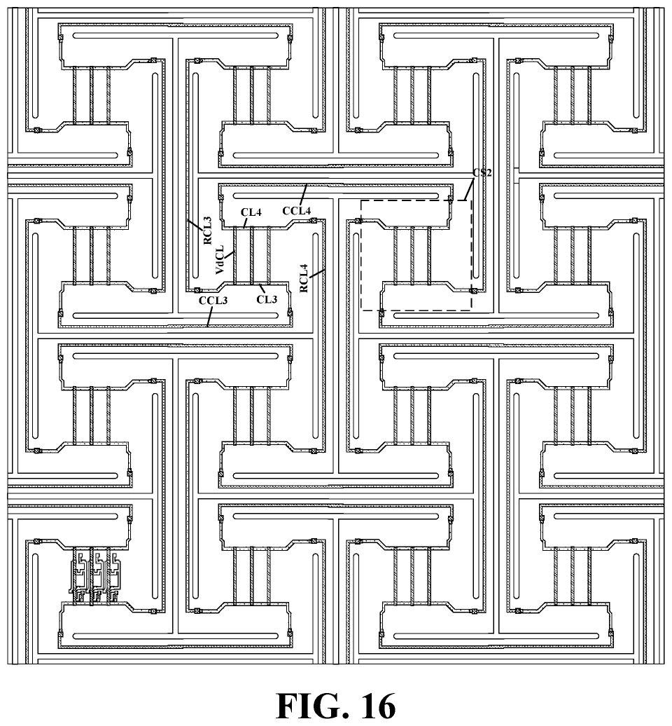

FIG. 10 illustrates the structure of a respective gate line of a plurality of gate lines configured to provide gate scanning signals to a row of islands of a plurality of islands in a display substrate in some embodiments according to the present disclosure. FIG. 11 illustrates the structure of a respective light emitting control signal line of a plurality of light emitting control signal lines configured to provide light emitting control signals to a row of islands of a plurality of islands in a display substrate in some embodiments according to the present disclosure. FIG. 12 illustrates the structure of a respective reset signal line of a plurality of reset signal lines configured to provide reset signals to a row of islands of a plurality of islands in a display substrate in some embodiments according to the present disclosure. FIG. 13 illustrates the structure of a respective reset control signal line of a plurality of reset control signal lines configured to provide reset control signals to a row of islands of a plurality of islands in a display substrate in some embodiments according to the present disclosure. FIG. 14 illustrates the structure of a respective data line of a plurality of data lines configured to provide data signals to a column of islands of a plurality of islands in a display substrate in some embodiments according to the present disclosure. FIG. 15 illustrates a first voltage supply network in a display area in a display substrate in some embodiments according to the present disclosure. FIG. 16 illustrates a second voltage supply network in a display area in a display substrate in some embodiments according to the present disclosure.

The structure of the display substrate is described based on the layouts of various layers of the display substrate depicted in FIG. 9A to FIG. 9N, in combination with the signal line connectivity depicted in FIG. 10 to FIG. 16. Referring to FIG. 9A to FIG. 9N, and FIG. 10, the respective gate line in some embodiments includes a first bridge gate connecting line BGL-1 at least partially in a first bridge of a plurality of bridges, a second bridge gate connecting line BGL-2 at least partially in a second bridge of a plurality of bridges, and a first gate branch line GL-1 connecting the first bridge gate connecting line BGL-1 and the second bridge gate connecting line BGL-2. The first gate branch line GL-1 is at least partially in a respective island of the plurality of islands. In some embodiments, the first gate branch line GL-1 is configured to provide a gate scanning signal to the second transistor T2 and the third transistor T3 in any one of the pixel driving circuits (e.g., sp1, sp2, or sp3) in the respective island.

In one example depicted in FIG. 9A to FIG. 9N, and FIG. 10, the first bridge gate connecting line BGL-1 and the second bridge gate connecting line BGL-2 are in a same layer (e.g., the first signal line layer), and the first gate branch line GL-1 is in a layer (e.g., the first conductive layer) different from the first bridge gate connecting line BGL-1 and the second bridge gate connecting line BGL-2.

Various appropriate implementations may be practiced in the present disclosure. In an alternative example, the first bridge gate connecting line BGL-1 and the second bridge gate connecting line BGL-2 are in a same layer as the first gate branch line GL-1.

In some embodiments, the first bridge gate connecting line BGL-1 connects the first gate branch line GL-1 in the respective island with an adjacent island of the plurality of islands in a first adjacent column (e.g., a previous column or a next column) and in a same row, for example, with a first gate branch line GL-1 in the adjacent island of the plurality of islands in the first adjacent column (e.g., the previous column or the next column) and in the same row.

In some embodiments, the second bridge gate connecting line BGL-2 connects the first gate branch line GL-1 in the respective island with an adjacent island of the plurality of islands in a second adjacent column (e.g., a next column or a previous column) and in a same row, for example, with a first gate branch line GL-1 in the adjacent island of the plurality of islands in the second adjacent column (e.g., the next column or the previous column) and in the same row. The first adjacent column and the second adjacent column are two different columns on two different sides, along a row direction, of a present column having the respective island of the plurality of islands.

In some embodiments, the respective gate line in the respective island further includes a second gate branch line GL-2. In some embodiments, the second gate branch line GL-2 is configured to provide a gate scanning signal to the sixth transistor T6 in any one of the pixel driving circuits (e.g., sp1, sp2, or sp3) in the respective island. Referring to FIG. 9A to FIG. 9N, and FIG. 10, in some embodiment, the respective gate line in the respective island further includes one or more gate connecting lines GCL connecting the first gate branch line GL-1 with the second gate branch line GL-2. In one example, the first gate branch line GL-1 and the second gate branch line GL-2 are in the first conductive layer, and the one or more gate connecting lines GCL are in the first signal line layer.

Referring to FIG. 9A to FIG. 9N, and FIG. 11, the respective light emitting control signal line in some embodiments includes a first bridge light emitting signal connecting line BemL-1 at least partially in a first bridge of a plurality of bridges, a second bridge light emitting signal connecting line BemL-2 at least partially in a second bridge of a plurality of bridges, and a light emitting signal connecting line emCL connecting the first bridge light emitting signal connecting line BemL-1 with the second bridge light emitting signal connecting line BemL-2. The light emitting signal connecting line emCL is at least partially in a respective island of the plurality of islands. In some embodiments, the light emitting signal connecting line emCL is configured to provide a light emitting control signal to the fourth transistor T4 and the fifth transistor T5 in any one of the pixel driving circuits (e.g., sp1, sp2, or sp3) in the respective island.

In one example depicted in FIG. 9A to FIG. 9N, and FIG. 11, the first bridge light emitting signal connecting line BemL-1 and the second bridge light emitting signal connecting line BemL-2 are in a same layer (e.g., the first signal line layer), and the light emitting signal connecting line emCL is in a layer (e.g., the first conductive layer) different from the first bridge light emitting signal connecting line BemL-1 and the second bridge light emitting signal connecting line BemL-2.

Various appropriate implementations may be practiced in the present disclosure. In an alternative example, the first bridge light emitting signal connecting line BemL-1 and the second bridge light emitting signal connecting line BemL-2 are in a same layer as the light emitting signal connecting line emCL.

In some embodiments, the first bridge light emitting signal connecting line BemL-1 connects the light emitting signal connecting line emCL in the respective island with an adjacent island of the plurality of islands in a first adjacent column (e.g., a previous column or a next column) and in a same row, for example, with a light emitting signal connecting line emCL in the adjacent island of the plurality of islands in the first adjacent column (e.g., the previous column or the next column) and in the same row.

In some embodiments, the second bridge light emitting signal connecting line BemL-2 connects the light emitting signal connecting line emCL in the respective island with an adjacent island of the plurality of islands in a second adjacent column (e.g., a next column or a previous column) and in a same row, for example, with a light emitting signal connecting line emCL in the adjacent island of the plurality of islands in the second adjacent column (e.g., the next column or the previous column) and in the same row. The first adjacent column and the second adjacent column are two different columns on two different sides, along a row direction, of a present column having the respective island of the plurality of islands.

Referring to FIG. 9A to FIG. 9N, and FIG. 12, the respective reset signal line in some embodiments includes a first bridge reset signal line Bvint-1 at least partially in a first bridge of a plurality of bridges, a second bridge reset signal line Bvint-2 at least partially in a second bridge of a plurality of bridges, a first reset signal branch line Vint-1 connected to the first bridge reset signal line Bvint-1, a second reset signal branch line Vint-2 connected to the second bridge reset signal line Bvint-2, and one or more first reset signal connecting lines Clr1 connecting the first reset signal branch line Vint-1 with the second reset signal branch line Vint-2. The first reset signal branch line Vint-1, the second reset signal branch line Vint-2, and the one or more first reset signal connecting lines Clr1 are at least partially in a respective island of the plurality of islands.

In one example depicted in FIG. 9A to FIG. 9N, and FIG. 12, the first bridge reset signal line Bvint-1, the second bridge reset signal line Bvint-2, and one or more first reset signal connecting lines Clr1 are in a same layer (e.g., the first signal line layer); and the first reset signal branch line Vint-1 and the second reset signal branch line Vint-2 are in a same layer (e.g., the second conductive layer). Optionally, the first reset signal branch line Vint-1 and the second reset signal branch line Vint-2 are in a layer different from the first bridge reset signal line Bvint-1, the second bridge reset signal line Bvint-2, and one or more first reset signal connecting lines Clr1.

Various appropriate implementations may be practiced in the present disclosure. In an alternative example, the first bridge reset signal line Bvint-1, the second bridge reset signal line Bvint-2, one or more first reset signal connecting lines Clr1 are in a same layer as the first reset signal branch line Vint-1 and the second reset signal branch line Vint-2.

In some embodiments, the first bridge reset signal line Bvint-1 connects the first reset signal branch line Vint-1 in the respective island with an adjacent island of the plurality of islands in a first adjacent column (e.g., a previous column or a next column) and in a same row, for example, with a first reset signal branch line Vint-1 in the adjacent island of the plurality of islands in the first adjacent column (e.g., the previous column or the next column) and in the same row.

In some embodiments, the second bridge reset signal line Bvint-2 connects the second reset signal branch line Vint-2 in the respective island with an adjacent island of the plurality of islands in a second adjacent column (e.g., a next column or a previous column) and in a same row, for example, with a second reset signal branch line Vint-2 in the adjacent island of the plurality of islands in the second adjacent column (e.g., the next column or the previous column) and in the same row. The first adjacent column and the second adjacent column are two different columns on two different sides, along a row direction, of a present column having the respective island of the plurality of islands.

In some embodiments, the respective reset signal line in the respective island further includes a second reset signal connecting line Clr2 and a third reset signal connecting line Clr3. The second reset signal connecting line Clr2 connects the first reset signal branch line Vint-1 to a first electrode of the first transistor T1. The third reset signal connecting line Clr3 connects the second reset signal branch line Vint-2 to a first electrode of the sixth transistor T6. In one example, the second reset signal connecting line Clr2 and the third reset signal connecting line Clr3 are in a first signal line layer, and the first reset signal branch line Vint-1 and the second reset signal branch line Vint-2 are in a second conductive layer.

Referring to FIG. 9A to FIG. 9N, and FIG. 13, the respective reset control signal line in some embodiments includes a first bridge reset control signal connecting line BrstL-1 at least partially in a first bridge of a plurality of bridges, a second bridge reset control signal connecting line BrstL-2 at least partially in a second bridge of a plurality of bridges, and a reset control signal connecting line rstCL connecting the first bridge reset control signal connecting line BrstL-1 with the second bridge reset control signal connecting line BrstL-2. The reset control signal connecting line rstCL is at least partially in a respective island of the plurality of islands. In some embodiments, the reset control signal connecting line rstCL is configured to provide a light emitting control signal to the first transistor T1 in any one of the pixel driving circuits (e.g., sp1, sp2, or sp3) in the respective island.

In one example depicted in FIG. 9A to FIG. 9N, and FIG. 11, the first bridge reset control signal connecting line BrstL-1 and the second bridge reset control signal connecting line BrstL-2 are in a same layer (e.g., the first signal line layer), and the reset control signal connecting line rstCL is in a layer (e.g., the first conductive layer) different from the first bridge reset control signal connecting line BrstL-1 and the second bridge reset control signal connecting line BrstL-2.

Various appropriate implementations may be practiced in the present disclosure. In an alternative example, the first bridge reset control signal connecting line BrstL-1 and the second bridge reset control signal connecting line BrstL-2 are in a same layer as the reset control signal connecting line rstCL.

In some embodiments, the first bridge reset control signal connecting line BrstL-1 connects the reset control signal connecting line rstCL in the respective island with an adjacent island of the plurality of islands in a first adjacent column (e.g., a previous column or a next column) and in a same row, for example, with a reset control signal connecting line rstCL in the adjacent island of the plurality of islands in the first adjacent column (e.g., the previous column or the next column) and in the same row.

In some embodiments, the second bridge reset control signal connecting line BrstL-2 connects the reset control signal connecting line rstCL in the respective island with an adjacent island of the plurality of islands in a second adjacent column (e.g., a next column or a previous column) and in a same row, for example, with a reset control signal connecting line rstCL in the adjacent island of the plurality of islands in the second adjacent column (e.g., the next column or the previous column) and in the same row. The first adjacent column and the second adjacent column are two different columns on two different sides, along a row direction, of a present column having the respective island of the plurality of islands.

Referring to FIG. 4, FIG. 9A to FIG. 9N, and FIG. 14, the display substrate incudes n number of data lines extending through a respective island and configured to provide data signals to n number of subpixels, n≥1. In one example depicted in FIG. 4, FIG. 9A to FIG. 9N, and FIG. 14, the display substrate includes three data lines extending through the respective island and configured to provide data signals to three subpixels, sp1, sp2, and sp3. A respective data line is configured to provide data signals to a corresponding subpixel.

Various appropriate implementations may be practiced in the present disclosure. In an alternative example, the display substrate includes one data line extending through the respective island and configured to provide data signals to one subpixel. In another alternative example, the display substrate includes four data lines extending through the respective island and configured to provide data signals to four subpixels (e.g., a red subpixel, two green subpixels, and a blue subpixel).

Referring to FIG. 9A to FIG. 9N, and FIG. 14, the respective data line in some embodiments includes a first bridge data line BDL-1 at least partially in a third bridge of a plurality of bridges, a second bridge data line BDL-2 at least partially in a fourth bridge of a plurality of bridges, a first data branch line DL-1 connected to the first bridge data line BDL-1, a second data branch line DL-2 connected to the second bridge data line BDL-2, and a data connecting line DCL connecting the first data branch line DL-1 with the second data branch line DL-2. The data connecting line DCL is at least partially in a respective island of the plurality of islands. Optionally, the first data branch line DL-1 and the second data branch line DL-2 are at least partially in the respective island. The data connecting line DCL is electrically connected to the first electrode of the second transistor, and configured to provide data signals to the first electrode of the second transistor.

In one example depicted in FIG. 9A to FIG. 9N, and FIG. 14, the first bridge data line BDL-1, the second bridge data line BDL-2, and the data connecting line DCL are in a same layer (e.g., the first signal line layer); and the first data branch line DL-1 and the second data branch line DL-2 are in a same layer (e.g., the first conductive layer). Optionally, the first data branch line DL-1 and the second data branch line DL-2 are in a layer different from the first bridge data line BDL-1, the second bridge data line BDL-2, and the data connecting line DCL.

Various appropriate implementations may be practiced in the present disclosure. In an alternative example, the first bridge data line BDL-1, the second bridge data line BDL-2, and the data connecting line DCL are in a same layer as the first data branch line DL-1 and the second data branch line DL-2.

In some embodiments, the first bridge data line BDL-1 connects the first data branch line DL-1 in the respective island with an adjacent island of the plurality of islands in a first adjacent row (e.g., a previous row or a next row) and in a same column, for example, with a first data branch line DL-1 in the adjacent island of the plurality of islands in the first adjacent row (e.g., the previous row or the next row) and in the same column.

In some embodiments, the second bridge data line BDL-2 connects the second data branch line DL-2 in the respective island with an adjacent island of the plurality of islands in a second adjacent row (e.g., a next row or a previous row) and in a same column, for example, with a second data branch line DL-2 in the adjacent island of the plurality of islands in the second adjacent row (e.g., the next row or the previous row) and in the same column. The first adjacent row and the second adjacent row are two different rows on two different sides, along a column direction, of a present row having the respective island of the plurality of islands.

Referring to FIG. 9A and FIG. 9J, the display substrate in the anode material layer in some embodiments includes one or more anode AD, a cathode connecting pad CDCP, and a cathode connecting line CDCL. The one or more anode AD, the cathode connecting pad CDCP, and the cathode connecting line CDCL are at least partially in a respective island of the plurality of islands Is. Optionally, the cathode connecting pad CDCP and the cathode connecting line CDCL are parts of a unitary structure. The cathode connecting pad CDCP and the cathode connecting line CDCL electrically connect a first connecting line CL1 to a cathode in the respective island, and electrically connect a second connecting line CL2 to the cathode in the respective island, thereby providing a second voltage supply signal to the cathode.

Referring to FIG. 9A and FIG. 9K, the display substrate includes the pixel definition layer PDL that defines a subpixel aperture. Referring to FIG. 9A and FIG. 9L, the display substrate in the light emitting layer includes one or more light emitting blocks EL. An orthographic projection of the one or more light emitting blocks EL on a base substrate at least partially overlaps with an orthographic projection of the one or more anodes on the base substrate.

Referring to FIG. 9A and FIG. 9M, the display substrate in the cathode material layer includes a cathode CD in a respective island of the plurality of islands Is.

Referring to FIG. 9A to FIG. 9N, in some embodiments, the display substrate includes a base substrate BS, a conductive layer CTL on the base substrate BS, an insulating layer IN on a side of the conductive layer CTL away from the base substrate BS, a signal line layer SLL on a side of the insulating layer IN away from the base substrate BS, a planarization layer PLN on a side of the signal line layer SLL away from the base substrate BS, an anode material layer on a side of the planarization layer PLN away from the base substrate BS, and a cathode material layer CML on a side of the anode material layer AML away from the base substrate BS.

In some embodiments, referring to FIG. 9N, the cathode connecting pad CDCP and the cathode connecting line CDCL is connected to (e.g., in direct contact with) the cathode CD. The cathode connecting pad CDCP is connected to a first connecting pad CP1 through a via extending through the second planarization layer PLN2. The first connecting pad CP1 is connected to a second connecting pad CP2 through a via extending through the first planarization layer PLN1. The second connecting pad CP2 is connected to the second connecting line CL2 through a via extending through the inter-layer dielectric layer ILD.

Optionally, the cathode connecting pad CDCP is in the anode material layer AML, the first connecting pad CP1 is in the second signal line layer SL2, the second connecting pad CP2 is in the first signal line layer SL1, and the second connecting line CL2 is in the second conductive layer CT2.

The cathode connecting line CDCL is connected to a third connecting pad CP3 through a via extending through the second planarization layer PLN2. The third connecting pad CP3 is connected to the fourth connecting pad CP4 through a via extending through the first planarization layer PLN1. The fourth connecting pad CP4 is connected to the first connecting line CL1 through a via extending through the inter-layer dielectric layer ILD.

Optionally, the cathode connecting line CDCL is in the anode material layer AML, the third connecting pad CP3 is in the second signal line layer SL2, the fourth connecting pad CP4 is in the first signal line layer SL1, and the first connecting line CL1 is in the second conductive layer CT2.

The cathode CD is electrically connected to the first connecting line CL1 and is electrically connected to the second connecting line CL2, thereby receiving a second voltage supply signal from the first connecting line CL1 and the second connecting line CL2.

Referring to FIG. 15, the first voltage supply network in some embodiments includes a plurality of first connecting structures CS1. Optionally, the plurality of first connecting structures CS1 are arranged in a first array of rows and columns. A respective first connecting structure of the plurality of first connecting structures CS1 in a region spaced apart from the peripheral area by at least a border row and at least a border column is connected to at least one of a first row connecting line RCL1, a second row connecting line RCL2, a first column connecting line CCL1, or a second column connecting line CCL2.

In some embodiments, the first row connecting line RCL1 connects a respective first connecting structure of the plurality of first connecting structures CS1 with a first connecting structure in a first adjacent row (e.g., a previous row or a next row) and in a same column together. In some embodiments, the second row connecting line RCL2 connects the respective first connecting structure with a first connecting structure in a second adjacent row (e.g., a next row or a previous row) and in a same column together. The first adjacent row and the second adjacent row are two different rows on two different sides, along a column direction, of a present row having the respective island of the plurality of islands.

In some embodiments, the first column connecting line CCL1 connects the respective first connecting structure with a first connecting structure in a first adjacent column (e.g., a previous column or a next column) and in a same row together. In some embodiments, the second column connecting line CCL2 connects the respective first connecting structure with a first connecting structure in a second adjacent column (e.g., a next column or a previous column) and in a same row together. The first adjacent column and the second adjacent column are two different columns on two different sides, along a row direction, of a present column having the respective island of the plurality of islands.

In some embodiments, the respective first connecting structure includes the first connecting line CL1 and the second connecting line CL2 electrically connected to each other. The first connecting line CL1 is connected to the first row connecting line RCL1 and the first column connecting line CCL1. The second connecting line CL2 is connected to the second row connecting line RCL2 and the second column connecting line CCL2. The respective first connecting structure further includes one or more connecting lines in a layer different from the first connecting line CL1 and the second connecting line CL2. Optionally, the respective first connecting structure further includes a structure in the anode material layer that connects the first connecting line CL1 and the second connecting line CL2 together. In one example, the structure in the anode material layer connecting the first connecting line CL1 and the second connecting line CL2 together includes a cathode connecting line CDCL and a cathode connecting pad CDCP. The structure in the anode material layer connecting the first connecting line CL1 and the second connecting line CL2 together is further connected to the cathode, as shown in FIG. 9N.

In one example, the first connecting line CL1 and the second connecting line CL2 are in the second conductive layer. The first row connecting line RCL1, the second row connecting line RCL2, the first column connecting line CCL1, and the second column connecting line CCL2, are in the second signal line layer. The cathode connecting line CDCL and the cathode connecting pad CDCP are in the anode material layer.

Each of the first connecting line CL1, the second connecting line CL2, the cathode connecting line CDCL and the cathode connecting pad CDCP is at least partially in the respective island of the plurality of islands. Each of the first row connecting line RCL1, the second row connecting line RCL2, the first column connecting line CCL1, and the second column connecting line CCL2 is at least partially in an individual bridge of the plurality of bridges. The first row connecting line RCL1, the second row connecting line RCL2, the first column connecting line CCL1, and the second column connecting line CCL2 are in four different bridges of the plurality of bridges. The four different bridges are connected to the respective island, respectively.

Referring to FIG. 16, the second voltage supply network in some embodiments includes a plurality of second connecting structures CS2. Optionally, the plurality of second connecting structures CS2 are arranged in a second array of rows and columns. A respective second connecting structure of the plurality of second connecting structures CS2 in a region spaced apart from the peripheral area by at least a border row and at least a border column is connected to at least one of a third row connecting line RCL3, a fourth row connecting line RCL4, a third column connecting line CCL3, or a fourth column connecting line CCL4.

In some embodiments, the third row connecting line RCL3 connects a respective second connecting structure of the plurality of second connecting structures CS2 with a second connecting structure in a first adjacent row (e.g., a previous row or a next row) and in a same column together. In some embodiments, the fourth row connecting line RCL4 connects the respective second connecting structure with a second connecting structure in a second adjacent row (e.g., a next row or a previous row) and in a same column together. The first adjacent row and the second adjacent row are two different rows on two different sides, along a column direction, of a present row having the respective island of the plurality of islands.

In some embodiments, the third column connecting line CCL3 connects the respective second connecting structure with a second connecting structure in a first adjacent column (e.g., a previous column or a next column) and in a same row together. In some embodiments, the fourth column connecting line CCL4 connects the respective second connecting structure with a second connecting structure in the first adjacent column (e.g., the previous column or the next column) and in the same row together. The first adjacent column and the second adjacent column are two different columns on two different sides, along a row direction, of a present column having the respective island of the plurality of islands.

In some embodiments, the respective second connecting structure includes a third connecting line CL3 and a fourth connecting line CL4 electrically connected to each other. The third connecting line CL3 is connected to the third row connecting line RCL3 and the third column connecting line CCL3. The fourth connecting line CL4 is connected to the fourth row connecting line RCL4 and the fourth column connecting line CCL4. The respective first connecting structure further includes one or more connecting lines in a layer different from the third connecting line CL3 and the fourth connecting line CL4. Optionally, the respective first connecting structure further includes one or more voltage supply connecting lines VdCL connecting the third connecting line CL3 and the fourth connecting line CL4 together.

In one example, the third connecting line CL3 and the fourth connecting line CL4 are in the first conductive layer; the one or more voltage supply connecting lines VdCL are in the first signal line layer; and the third row connecting line RCL3, the third column connecting line CCL3, the fourth row connecting line RCL4, and the fourth column connecting line CCL4 are in the second signal line layer.

Each of the third connecting line CL3, the fourth connecting line CL4, and the one or more voltage supply connecting lines VdCL is at least partially in the respective island of the plurality of islands. Each of the third row connecting line RCL3, the third column connecting line CCL3, the fourth row connecting line RCL4, and the fourth column connecting line CCL4 in the second signal line layer is at least partially in an individual bridge of the plurality of bridges. The third row connecting line RCL3, the fourth row connecting line RCL4, the third column connecting line CCL3, and the fourth column connecting line CCL4 are in four different bridges of the plurality of bridges. The four different bridges are connected to the respective island, respectively.

Various appropriate implementations may be practiced in the present disclosure. In some embodiments, the first voltage supply network is used for providing a first voltage supply signal, the second voltage supply network is used for providing a second voltage supply signal, and the plurality of reset signal lines are used for providing a reset signal. In alternative embodiments, the first voltage supply network (e.g., the structure depicted in FIG. 15) may be used for providing the second voltage supply signal, or the reset signal. In alternative embodiments, the second voltage supply network (e.g., the structure depicted in FIG. 16) may be used for providing the first voltage supply signal, or the reset signal. In alternative embodiments, the plurality of reset signal lines (e.g., the structure depicted in FIG. 12) may be used for providing the first voltage supply signal, or the second voltage supply signal.

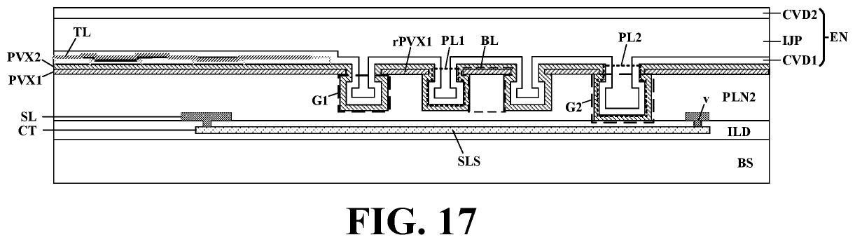

FIG. 17 is a cross-sectional view along a C-C′ line in FIG. 9A. Referring to FIG. 9A, FIG. 9I, and FIG. 17, the display substrate in some embodiments includes one or more first grooves G1 in the respective island of the plurality of islands. A respective first groove of the one or more first grooves G1 substantially surrounds a region having transistors and capacitors of the one or more pixel driving circuits of the respective island. As used herein the term “substantially surrounding” refers to surrounding at least 50% (e.g., at least 60%, at least 70%, at least 80%, at least 90%, at least 95%, at least 99%, and 100%) of a perimeter of an area.

In some embodiments, the respective first groove of the one or more first grooves G1 at least partially extends into a planarization layer (e.g., the second planarization layer PLN2).

In some embodiments, the display substrate further includes a first passivation layer PVX1 on a side of the second planarization layer PLN2 away from the base substrate BS, a second passivation layer PVX2 on a side of the first passivation layer PVX1 away from the base substrate BS, and an encapsulating layer EN on a side of the second passivation layer PVX2 away from the base substrate BS. Optionally, the encapsulating layer EN includes a first inorganic encapsulating sub-layer CVD1, an organic encapsulating sub-layer IJP on a side of the first inorganic encapsulating sub-layer CVD1 away from the base substrate BS, and a second inorganic encapsulating sub-layer CVD2 on a side of the organic encapsulating sub-layer IJP away from the base substrate BS.

In some embodiments, the encapsulating layer EN includes one or more first pillars PL1. A respective first pillar of the one or more first pillars PL1 extends into the respective first groove. Optionally, the respective first pillar substantially surrounds a region having transistors and capacitors of the one or more pixel driving circuits of the respective island.

In some embodiments, the respective first pillar includes a portion of the first inorganic encapsulating sub-layer CVD1 extending into the respective first groove. Optionally, the respective first pillar further includes a portion of the organic encapsulating sub-layer IJP extending into the respective first groove. In one example, in the respective first groove, the portion of the first inorganic encapsulating sub-layer CVD1 is in direct contact with the second planarization layer PLN2. Various appropriate organic materials and various appropriate methods may be used for making the organic encapsulating sub-layer IJP. The organic encapsulating sub-layer IJP may be an overcoat layer or may be formed by ink jet printing.

In some embodiments, the display substrate includes one or more barrier structures BL. A respective barrier structure of the one or more barrier structures BL is between two adjacent first groove of the one or more first grooves G1. Due to the presence of the respective barrier structure, in the process of depositing a first passivation material, the first passivation material deposited on the display substrate segregates into residual layers on top of the respective barrier structure. FIG. 17 illustrates a residual first passivation material layer rPVX1 segregated from the first passivation layer PVX1 due to the presence of the respective barrier structure. The residual first passivation material layer rPVX1 is on a side of a portion of the second planarization layer PLN2 away from the base substrate BS. The respective barrier structure includes the residual first passivation material layer rPVX1 and the portion of the second planarization layer PLN2.

In some embodiments, the display substrate further includes one or more second grooves G2. Optionally, the display substrate further includes one or more second pillars PL2. A respective second pillar of the one or more second pillars PL2 extends into a respective second groove of the one or more second grooves G2. Referring to FIG. 9I, in one example, the display substrate includes four second pillars. The respective second pillar is between two adjacent bridges of the plurality of bridges connected to the respective island. Optionally, an orthographic projection of the second planarization layer PLN2 on the base substrate at least partially overlaps (e.g., covers) orthographic projections of the plurality of bridges and the one or more second pillars PL2 on the base substrate. Optionally, A respective second groove of the one or more second grooves G2 partially surrounds a region having transistors and capacitors of the one or more pixel driving circuits of the respective island.

In some embodiments, the respective second pillar includes a portion of the first inorganic encapsulating sub-layer CVD1 extending into the respective second groove. Optionally, the respective second pillar further includes a portion of the organic encapsulating sub-layer IJP extending into the respective second groove. In one example, in the respective second groove, the portion of the first inorganic encapsulating sub-layer CVD1 is in direct contact with the second passivation layer PVX2.

By having the one or more second pillars PL2, the encapsulating layer EN is in direct contact with the second passivation layer PVX2, which is made of an inorganic insulating material. The structure can effectively prevent oxygen and moisture from entering the respective island through one or more organic material layers.

In some embodiments, one or more signal lines SLS cross over the one or more first pillars PL1 and the one or more second pillars PL2. For example, referring to FIG. 9A to FIG. 9N, and FIG. 17, a respective light emitting control signal line of the plurality of light emitting control signal lines crosses over the one or more first pillars PL1 and the one or more second pillars PL2. In some embodiments, the one or more signal lines SLS includes a portion in a signal line layer SL (e.g., the first signal line layer SL1) and a portion in a conductive layer CT (e.g., the first conductive layer CT1). The portion in the conductive layer CT crosses over the one or more first pillars PL1 and the one or more second pillars PL2. Referring to FIG. 9A, FIG. 9C, and FIG. 9I, in one example, the light emitting signal connecting line emCL crosses over the one or more first pillars PL1 and the one or more second pillars PL2. An orthographic projection of the one or more signal lines SLS on the base substrate partially overlaps with an orthographic projection of the one or more first pillars PL1 and the one or more second pillars PL2 on the base substrate. By having the portion of the one or more signal lines SLS in the conductive layer CT, the one or more signal lines SLS can extend through the area having the one or more first pillars PL1 and the one or more second pillars PL2 without interfering the encapsulating structure.

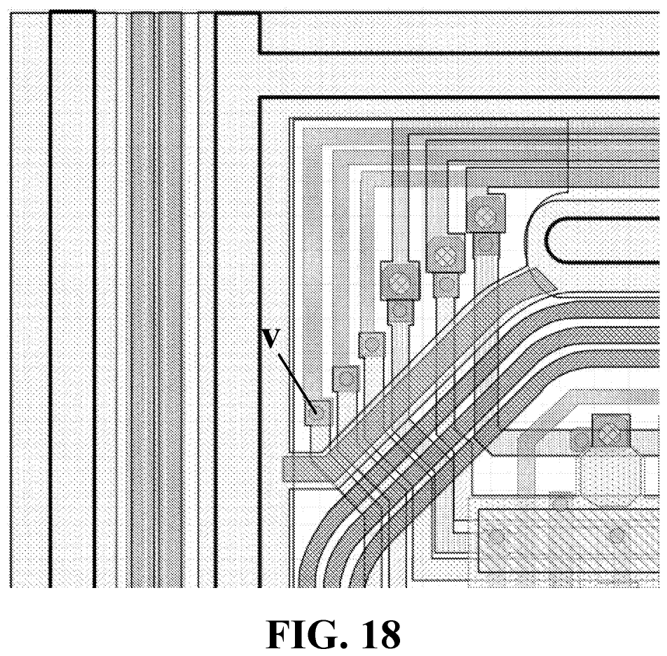

FIG. 18 illustrates layout of signal lines in a region of the display substrate. Referring to FIG. 17 and FIG. 18, the display substrate further includes a via v extending through the inter-layer dielectric layer ILD, the portion of the one or more signal lines SLS in a signal line layer SL connects to the portion of the one or more signal lines SLS in the conductive layer CT through the via v. In this region, deformation stress is relatively large when the display substrate is subject to stretch. The inventors of the present disclosure discover that line breaks can be obviated by having the via v in a position close to the respective second pillar. In one example, a distance between the via v and the respective second pillar is 4.5 μm.

Referring to FIG. 17, a transmission line TL is denoted in FIG. 17. In some embodiments, the transmission line TL may be one of a portion of a respective light emitting control signal line, a portion of a respective reset signal line, or a portion of a respective gate line.

In another example, an orthographic projection of the respective second pillar on the base substrate partially overlaps with an orthographic projection of the via v on the base substrate.

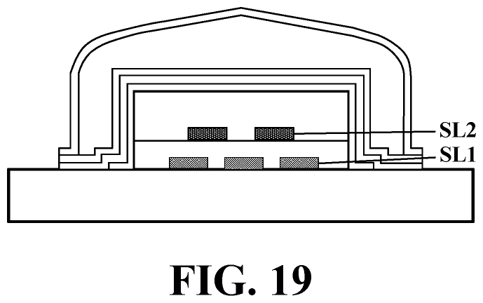

FIG. 19 is a cross-sectional view along a D-D′ line in FIG. 9A. FIG. 19 illustrates a layout of signal line extending through a respective bridge. As shown in FIG. 19, the signal line extending through the respective bridge in some embodiments includes one or more signal lines in the first signal line layer SL1 and one or more signal lines in the second signal line layer SL2. An orthographic projection of the one or more signal lines in the first signal line layer SL1 on the base substrate at least partially overlaps with an orthographic projection of the one or more signal lines in the second signal line layer SL2 on the base substrate.

In another aspect, the present invention provides a display apparatus, including the display substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating a display substrate. In some embodiments, the method includes forming a plurality of islands and forming a plurality of bridges connecting the plurality of islands. Optionally, the method further comprises forming a signal line. Optionally, forming the signal line includes forming a first bridge connecting line at least partially in a first bridge of a plurality of bridges; forming a second bridge connecting line at least partially in a second bridge of the plurality of bridges; and forming a connecting structure at least partially in a respective island of the plurality of islands, connecting the first bridge connecting line with the second bridge connecting line. Optionally, at least a portion of the connecting structure is formed in a layer different from the first bridge connecting line or the second bridge connecting line.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display substrate, comprising a plurality of islands and a plurality of bridges connecting the plurality of islands;
wherein the display substrate comprises a signal line;
wherein the signal line comprises:
a first bridge connecting line at least partially in a first bridge of the plurality of bridges;
a second bridge connecting line at least partially in a second bridge of the plurality of bridges; and
a connecting structure at least partially in a respective island of the plurality of islands, connecting the first bridge connecting line with the second bridge connecting line;
wherein at least a portion of the connecting structure is in a layer different from the first bridge connecting line or the second bridge connecting line.

2. The display substrate of claim 1, wherein the first bridge connecting line connects the connecting structure with a connecting structure in an adjacent island of the plurality of islands in a first adjacent column and in a same row; and
the second bridge connecting line connects the connecting structure with a connecting structure in an adjacent island of the plurality of islands in a second adjacent column and in a same row.

3. The display substrate of claim 1, wherein the first bridge connecting line connects the connecting structure with a connecting structure in an adjacent island of the plurality of islands in a first adjacent row and in a same column; and
the second bridge connecting line connects the connecting structure with a connecting structure in an adjacent island of the plurality of islands in a second adjacent row and in a same column.

4. The display substrate of claim 1, wherein at least the portion of the connecting structure is in a first conductive layer; and
the first bridge connecting line and the second bridge connecting line are in a first signal line layer spaced apart from the first conductive layer by one or more insulating layers.

5. The display substrate of claim 4, comprising a plurality of gate lines;
wherein the signal line is a respective gate line of the plurality of gate lines;
the first bridge connecting line is a first bridge gate connecting line; and
the second bridge connecting line is a second bridge gate connecting line;
wherein the connecting structure comprises a first gate branch line connecting the first bridge gate connecting line and the second bridge gate connecting line;
the first gate branch line is configured to provide a gate scanning signal to a data write transistor and a compensating transistor in a pixel driving circuit in the respective island.

6. The display substrate of claim 5, wherein the connecting structure further comprises:
a second gate branch line configured to provide a control signal to a reset transistor; and
one or more gate connecting lines connecting the first gate branch line with the second gate branch line;
wherein the first gate branch line and the second gate branch line are in the first conductive layer; and
the one or more gate connecting lines are in the first signal line layer.

7. The display substrate of claim 4, comprising a plurality of light emitting control signal lines;
wherein the signal line is a respective light emitting control signal line of the plurality of light emitting control signal lines;
the first bridge connecting line is a first bridge light emitting signal connecting line; and
the second bridge connecting line is a second bridge light emitting signal connecting line;
wherein the connecting structure comprises a light emitting signal connecting line connecting the first bridge light emitting signal connecting line with the second bridge light emitting signal connecting line; and
the light emitting signal connecting line is configured to provide a light emitting control signal to a first light emitting control transistor and a second light emitting control transistor.

8. The display substrate of claim 4, comprising a plurality of reset control signal lines;
wherein the signal line is a respective reset control signal line of the plurality of reset control signal lines;
the first bridge connecting line is a first bridge reset control signal connecting line; and
the second bridge connecting line is a second bridge reset control signal connecting line;
wherein the connecting structure comprises a reset control signal connecting line connecting the first bridge reset control signal connecting line and the second bridge reset control signal connecting line.

9. The display substrate of claim 4, comprising a plurality of data lines;
wherein the signal line is a respective data line of the plurality of data lines;
the first bridge connecting line is a first bridge data line;
the second bridge connecting line is a second bridge data line;
wherein the connecting structure comprises:
a first data branch line connected to the first bridge data line;
a second data branch line connected to the second bridge data line; and
a data connecting line connecting the first data branch line and the second data branch line.

10. The display substrate of claim 9, wherein the first bridge data line, the second bridge data line, and the data connecting line are in the first signal line layer; and
the first data branch line and the second data branch line are in the first conductive layer.

11. The display substrate of claim 1, wherein at least the portion of the connecting structure is in a second conductive layer; and
the first bridge connecting line and the second bridge connecting line are in a second signal line layer spaced apart from a first conductive layer by one or more insulating layers.

12. The display substrate of claim 11, comprising a plurality of reset signal lines;
wherein the signal line is a respective reset signal line of the plurality of reset signal lines;
the first bridge connecting line is a first bridge reset signal line; and
the second bridge connecting line is a second bridge reset signal line;
wherein the connecting structure comprises:
a first reset signal branch line connected to the first bridge reset signal line;
a second reset signal branch line connected to the second bridge reset signal line; and
one or more first reset signal connecting lines connecting the first reset signal branch line with the second reset signal branch line.

13. The display substrate of claim 12, wherein the first reset signal branch line and the second reset signal branch line are in the second conductive layer; and
the one or more first reset signal connecting lines are in a first signal line layer.

14. A display substrate, comprising a plurality of islands and a plurality of bridges connecting the plurality of islands;
wherein the display substrate comprises a first voltage supply network;
wherein the first voltage supply network comprises a plurality of first connecting structures in a display area of the display substrate, a first row connecting line, a second row connecting line, a first column connecting line, and a second column connecting line;
a respective first connecting structure of the plurality of first connecting structures is connected by the first row connecting line, the second row connecting line, the first column connecting line, and the second column connecting line, to four adjacent first connecting structures, respectively; and
the first row connecting line, the second row connecting line, the first column connecting line, and the second column connecting line are in four different bridges of the plurality of bridges.

15. The display substrate of claim 14, wherein the first row connecting line connects the respective first connecting structure with a first connecting structure in a first adjacent row and in a same column together;
the second row connecting line connects the respective first connecting structure with a first connecting structure in a second adjacent row and in a same column together; and
the first adjacent row and the second adjacent row are two different rows on two different sides, along a column direction, of a present row having the respective first connecting structure.

16. The display substrate of claim 14, wherein the first column connecting line connects the respective first connecting structure with a first connecting structure in a first adjacent column and in a same row together;
the second column connecting line connects the respective first connecting structure with a first connecting structure in a second adjacent column and in a same row together; and
the first adjacent column and the second adjacent column are two different columns on two different sides, along a row direction, of a present column having the respective first connecting structure.

17. The display substrate of claim 14, wherein the respective first connecting structure comprises a first connecting line and a second connecting line electrically connected to each other;
the first connecting line is connected to the first row connecting line and the first column connecting line; and
the second connecting line is connected to the second row connecting line and the second column connecting line.

18. (canceled)

19. The display substrate of claim 14, further comprising a second voltage supply network;
wherein the second voltage supply network comprises a plurality of second connecting structures in a display area of the display substrate, a third row connecting line, a fourth row connecting line, a third column connecting line, and a fourth column connecting line;
a respective second connecting structure of the plurality of second connecting structures is connected by the third row connecting line, the fourth row connecting line, the third column connecting line, and the fourth column connecting line, to four adjacent second connecting structures, respectively;
the third row connecting line, the fourth row connecting line, the third column connecting line, and the fourth column connecting line are in the four different bridges.

20. (canceled)

21. (canceled)

22. (canceled)

23. (canceled)

24. A display substrate, comprising a plurality of islands and a plurality of bridges connecting the plurality of islands;
wherein the display substrate comprises:
a base substrate;
a planarization layer;
an encapsulating layer on a side of the planarization layer away from the base substrate; and
one or more first grooves in a respective island of the plurality of islands, the one or more first grooves at least partially extending into the planarization layer; and
a respective first groove of the one or more first grooves substantially surrounds a region having transistors and capacitors of one or more pixel driving circuits of the respective island;
wherein the encapsulating layer comprises one or more first pillars;
a respective first pillar of the one or more first pillars extends into the respective first groove; and
the respective first pillar substantially surrounds a region having transistors and capacitors of the one or more pixel driving circuits of the respective island.

25. (canceled)

26. (canceled)

27. (canceled)

28. (canceled)

29. A display apparatus, comprising the display substrate of claim 1, and one or more integrated circuits connected to the display substrate.
